(19) United States
(12) Patent Application Publication
(10) Pub. No.: US 2023/0041025 A1
(43) Pub. Date: Feb. 9, 2023

(54) NEGATIVE-WORKING PHOTOSENSITIVE RESIN COMPOSITION, PHOTOSENSITIVE RESIST FILM, PATTERN FORMATION METHOD, CURED FILM, CURED FILM PRODUCTION METHOD, AND ROLLED BODY

(71) Applicant: Tokyo Ohka Kogyo Co., Ltd., Kawasaki-shi (JP)

(72) Inventors: Ryosuke NAKAMURA, Kawasaki-shi (JP); Takahiro KONDO, Kawasaki-shi (JP); Hiroaki TAKEUCHI, Kawasaki-shi (JP); Hirofumi IMAI, Kawasaki-shi (JP)

(73) Assignee: Tokyo Ohka Kogyo Co., Ltd., Kawasaki-shi (JP)

(21) Appl. No.: 17/754,247

(22) PCT Filed: Oct. 5, 2020
(86) PCT No.: PCT/JP2020/037682

§ 371 Date: Mar. 28, 2022

(30) Foreign Application Priority Data
Oct. 8, 2019 (JP) 2019-185122

(51) Int. Cl. G03F 7/038; C08G 59/32

(52) U.S. Cl. CPC G03F 7/038; C08G 59/3245; G03F 7/168

(57) ABSTRACT

A negative-working photosensitive resin composition including an epoxy group-containing resin, a metal oxide, and a cationic polymerization initiator, in which a photosensitive resin film having a film thickness of 20 μm obtained by applying the negative-working photosensitive resin composition onto a silicon wafer and performing a bake treatment at 90° C. for 5 minutes has a Martens hardness of less than 235 [N/mm²], and when a viscoelasticity of a cured film, which is obtained by exposing the photosensitive resin film to i-rays at an irradiation amount of 200 mJ/cm², performing a bake treatment after the exposure at 90° C. for 5 minutes, and then performing a bake treatment at 200° C. for 1 hour to cure the photosensitive resin film, is measured at a frequency of 1.0 Hz, a tensile elastic modulus (E*) of the cured film at a temperature of 175° C. is 2.1 [GPa] or more.

### TECHNICAL FIELD

The present invention relates to a negative-working photosensitive resin composition, a photosensitive resist film, a pattern formation method, a cured film, a cured film production method, and a rolled body. Priority is claimed on Japanese Patent Application No. 2019-185122, filed on Oct. 8, 2019, the content of which is incorporated herein by reference.

### BACKGROUND ART

In recent years, development of microelectronic devices such as a surface acoustic wave (SAW) filter has been promoted. A package encapsulating such an electronic device has a hollow structure for ensuring propagation of the surface acoustic wave and mobility of movable members in the electronic device.

The above-described hollow structure is formed by molding a photosensitive material while keeping a wiring board on which electrodes are formed hollow. In the photosensitive material used here, a thinner and harder cured film is required.

In the related art, as the photosensitive material for forming the hollow structure, a negative-working photosensitive resin composition containing an epoxy group-containing resin, a metal oxide, and a specific cationic polymerization initiator which generates relatively strong acids upon exposure, and a photosensitive resist film are disclosed. According to the negative-working photosensitive resin composition and the photosensitive resist film, a pattern having a favorable shape can be formed, and the hardness of the cured film is improved (see Patent Document 1).

### CITATION LIST

### Patent Document

### [Patent Document 1]

Japanese Unexamined Patent Application, First Publication No. 2018-36533

### SUMMARY OF INVENTION

### Technical Problem

As the development of microelectronic devices progresses, a height of a module is currently required to be further reduced. Along with this, in the above-described package, it is necessary to miniaturize the hollow structure while securing a space in a vicinity of the electrodes formed on the wiring board.

However, in a case where the hollow structure is miniaturized in such a way, in a cured film obtained by curing the negative-working photosensitive resin composition or photosensitive resist film in the related art, the hardness is insufficient, and for example, it may be difficult to maintain the hollow structure against a high pressure applied during molding.

On the other hand, in the photosensitive resist film, in a case where the hardness of the film is simply increased to improve the strength after curing, for example, in a case where a master roll is produced, there is a risk that the film may be cracked or poorly crimped, or that the film may be poorly attached to a silicon wafer or the like.

The present invention has been made in consideration of the above-described problems, and an object of the present invention is to provide a photosensitive resist film which is capable of obtaining a cured film having a higher hardness, is easy to roll, and has excellent laminating properties for a substrate or the like, a negative-working photosensitive resin composition capable of producing the photosensitive resist film, a pattern formation method, a cured film and a cured film production method, and a rolled body.

### Solution to Problem

The present invention includes the following aspects.

According to a first aspect of the present invention, there is provided a negative-working photosensitive resin composition, which forms a negative-working pattern by a development using a developing solution containing an organic solvent, including an epoxy group-containing resin (A), a metal oxide (M), and a cationic polymerization initiator (T), in which, in a case of applying the negative-working photosensitive resin composition onto a silicon wafer and performing a bake treatment at 90° C. for 5 minutes to obtain a photosensitive resin film having a film thickness of 20 μm, the film has a Martens hardness of less than 235 [N/mm²], and in a case where a viscoelasticity of a cured film, which is obtained by exposing the photosensitive resin film to i-rays at an irradiation amount of 200 mJ/cm², performing a bake treatment after the exposure at 90° C. for 5 minutes, and then performing a bake treatment at 200° C. for 1 hour to cure the photosensitive resin film, is measured at a frequency of 1.0 Hz, a tensile elastic modulus (E*) of the cured film at a temperature of 175° C. is 2.1 [GPa] or more.

According to a second aspect of the present invention, there is provided a photosensitive resist film obtained by laminating a negative-working photosensitive resin film containing an epoxy group-containing resin (A), a metal oxide (M), and a cationic polymerization initiator (I) on a base film, in which, in a case where the photosensitive resin film is laminated on a silicon wafer to a film thickness of 20 μm, the photosensitive resin film has a Martens hardness of less than 235 [N/mm²], and in a case where a viscoelasticity of a cured film, which is obtained by exposing the photosensitive resin film to i-rays at an irradiation amount of 200 mJ/cm², performing a bake treatment after the exposure at 90° C. for 5 minutes, and then performing a bake treatment at 200° C. for 1 hour to cure the photosensitive resin film, is measured at a frequency of 1.0 Hz, a tensile elastic modulus (E*) of the cured film at a temperature of 175° C. is 2.1 [GPa] or more.

According to a third aspect of the present invention, there is provided a pattern formation method including: a step of forming a photosensitive resin film on a support using the negative-working photosensitive resin composition according to the first aspect or the photosensitive resist film according to the second aspect; a step of exposing the photosensitive resin film; and a step of developing the exposed photosensitive resin film to form a negative-working pattern.

According to a fourth aspect of the present invention, there is provided a cured film obtained by curing the negative-working photosensitive resin composition according to the first aspect.

According to a fifth aspect of the present invention, there is provided a cured film production method including: a step of forming a photosensitive resin film on a support using the negative-working photosensitive resin composition according to the first aspect or the photosensitive resist film according to the second aspect; and a step of curing the photosensitive resin film to obtain a cured film.

According to a sixth aspect of the present invention, there is provided a rolled body obtained by winding the photosensitive resist film according to the second aspect around a winding core.

### Advantageous Effects of Invention

According to the present invention, it is possible to provide a photosensitive resist film which is capable of obtaining a cured film having a higher hardness, is easy to roll, and has excellent laminating properties for a substrate or the like, a negative-working photosensitive resin composition capable of producing the photosensitive resist film, a pattern formation method, a cured film and a cured film production method, and a rolled body.

### DESCRIPTION OF EMBODIMENTS

In the present specification and claims, the term “aliphatic” is a relative concept used with respect to the term “aromatic” and defines a group which no aromaticity, a compound with no aromaticity, or the like.

The term “alkyl group” includes linear, branched, or cyclic monovalent saturated hydrocarbon groups unless otherwise specified. The same applies to an alkyl group in an alkoxy group.

The term “alkylene group” includes linear, branched, or cyclic divalent saturated hydrocarbon groups unless otherwise specified.

A “halogenated alkyl group” is a group in which some or all hydrogen atoms in an alkyl group are replaced with halogen atoms. Examples of the halogen atom include a fluorine atom, a chlorine atom, a bromine atom, and an iodine atom.

A “fluorinated alkyl group” refers to a group in which some or all hydrogen atoms in an alkyl group are replaced with fluorine atoms.

The term “constitutional unit” indicates a monomer unit constituting a polymer compound (a resin, a polymer, or a copolymer).

The expression “may have a substituent” includes a case where a hydrogen atom (—H) is replaced with a monovalent group and a case where a methylene group (—CH₂—) is replaced with a divalent group.

The term “exposure” is used as a general concept for irradiation with radiation.

(Negative-Working Photosensitive Resin Composition)

A negative-working photosensitive resin composition (hereinafter, may be simply referred to as a “photosensitive composition”) according to the present embodiment contains an epoxy group-containing resin (A), a metal oxide (M), and a cationic polymerization initiator (I). Hereinafter, each of these components is also referred to as a component (A), a component (M), and a component (I).

In addition, in the photosensitive composition according to the present embodiment, in a case of applying the negative-working photosensitive resin composition onto a silicon wafer and performing a bake treatment at 90° C. for 5 minutes to obtain a photosensitive resin film having a film thickness of 20 μm, the film has a Martens hardness of less than 235 [N/mm²], and in a case where a viscoelasticity of a cured film, which is obtained by exposing the photosensitive resin film to i-rays at an irradiation amount of 200 mJ/cm², performing a bake treatment after the exposure at 90° C. for 5 minutes, and then performing a bake treatment at 200° C. for 1 hour to cure the photosensitive resin film, is measured at a frequency of 1.0 Hz, a tensile elastic modulus (E*) of the cured film at a temperature of 175° C. is 2.1 [GPa] or more.

In a case where a photosensitive resin film is formed of such a photosensitive composition and selective exposure is performed on the photosensitive resin film, since a cation moiety of the component (I) is decomposed to generate an acid in an exposed portion of the photosensitive resin film, and an epoxy group in the component (A) is subjected to ring-opening polymerization due to an action of the acid so that the solubility of the component (A) in a developing solution containing an organic solvent is decreased while the solubility of the component (A) in the developing solution containing an organic solvent is not changed in an unexposed portion of the photosensitive resin film. Therefore, a difference in solubility in the developing solution containing an organic solvent occurs between the exposed portion of the photosensitive resin film and the unexposed portion of the photosensitive resin film. Accordingly, in a case where the photosensitive resin film is developed with the developing solution containing an organic solvent, the unexposed portion is dissolved and removed so that a negative-working pattern is formed.

<Epoxy Group-Containing Resin (A)>

The epoxy group-containing resin (component (A)) is not particularly limited as long as the resin has an epoxy group sufficient enough to form a pattern upon exposure, in one molecule.

Examples of the component (A) include a novolak type epoxy resin (Anv), a bisphenol A type epoxy resin (Abp), a bisphenol F type epoxy resin, an aliphatic epoxy resin, and an acrylic resin (Aac).

<<Novolak Type Epoxy Resin (any)>>

Suitable examples of the novolak type epoxy resin (Anv) include a resin (A1) (hereinafter, also referred to as a “component (A1)”) represented by Formula (A1).

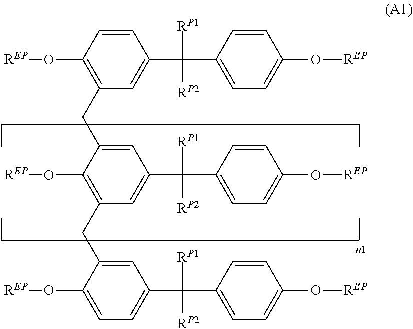

[in the formula, R^{p1} and R^{p2} each independently represent a hydrogen atom or an alkyl group having 1 to 5 carbon atoms, a plurality of R^{p1}'s may be the same as or different from one another, a plurality of R^{p2}'s may be the same as or different from one another, n₁ represents an integer of 1 to 5, R^{EP} represents an epoxy group-containing group, and a plurality of R^{EP}'s may be the same as or different from one another]

In Formula (A1), the alkyl group having 1 to 5 carbon atoms as R^{p1} and R^{p2} is, for example, a linear, branched, or cyclic alkyl group having 1 to 5 carbon atoms. Examples of the linear or branched alkyl group include a methyl group, an ethyl group, a propyl group, an isopropyl group, an n-butyl group, an isobutyl group, a tert-butyl group, a pentyl group, an isopentyl group, and a neopentyl group. Further, examples of the cyclic alkyl group include a cyclobutyl group and a cyclopentyl group.

Among these, R^{p1} and R^{p2} are preferably a hydrogen atom or a linear or branched alkyl group, more preferably a hydrogen atom or a linear alkyl group, and particularly preferably a hydrogen atom or a methyl group.

In Formula (A1), a plurality of RP's may be the same as or different from one another. A plurality of R^{p2}'s may be the same as or different from one another.

In Formula (A1), n₁ is an integer of 1 to 5, preferably 2 or 3, and more preferably 2.

In Formula (A1), R^{EP} is an epoxy group-containing group.

The epoxy group-containing group as R^{EP} is not particularly limited, and examples thereof include a group consisting of only an epoxy group; a group consisting only an alicyclic epoxy group; and a group having an epoxy group or an alicyclic epoxy group and a divalent linking group.

The alicyclic epoxy group is an alicyclic group having an oxacyclopropane structure as a 3-membered ring ether. Specifically, the alicyclic epoxy group is a group having an alicyclic group and an oxacyclopropane structure.

An alicyclic group which is a basic skeleton of the alicyclic epoxy group may be monocyclic or polycyclic. Examples of the monocyclic alicyclic group include a cyclopropyl group, a cyclobutyl group, a cyclopentyl group, a cyclohexyl group, a cycloheptyl group, and a cyclooctyl group. Further, examples of the polycyclic alicyclic group include a norbornyl group, an isobornyl group, a tricyclononyl group, a tricyclodecyl group, and a tetracyclododecyl group. Further, a hydrogen atom in these alicyclic groups may be replaced with an alkyl group, an alkoxy group, a hydroxyl group, and the like.

In a case of the group having an epoxy group or an alicyclic epoxy group and a divalent linking group, it is preferable that the epoxy group or the alicyclic epoxy group is bonded through a divalent linking group bonded to an oxygen atom (—O—) in the formula.

Here, the divalent linking group is not particularly limited, and suitable examples thereof include a divalent hydrocarbon group which may have a substituent and a divalent linking group including a hetero atom.

Regarding the divalent hydrocarbon group which may have a substituent:

such a divalent hydrocarbon group may be an aliphatic hydrocarbon group or an aromatic hydrocarbon group; and

the aliphatic hydrocarbon group in the divalent hydrocarbon group may be saturated or unsaturated, and in general, it is preferable that the aliphatic hydrocarbon group is saturated.

More specific examples of the aliphatic hydrocarbon group include a linear or branched aliphatic hydrocarbon group and an aliphatic hydrocarbon group including a ring in the structure thereof.

The number of carbon atoms in the above-described linear aliphatic hydrocarbon group is preferably 1 to 10, more preferably 1 to 6, still more preferably 1 to 4, and most preferably 1 to 3. As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄-] and a pentamethylene group [—(CH₂)₅—].

The number of carbon atoms in the above-described branched aliphatic hydrocarbon group is preferably 2 to 10, more preferably 2 to 6, still more preferably 2 to 4, and most preferably 2 to 3. As the branched aliphatic hydrocarbon group, a branched alkylene group is preferable. Specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂— and —CH₂CH(CH₃)CH₂CH₂—. As an alkyl group in the alkylalkylene group, a linear alkyl group having 1 to 5 carbon atoms is preferable.

Examples of the aliphatic hydrocarbon group including a ring in the structure thereof include an alicyclic hydrocarbon group (a group formed by removing two hydrogen atoms from an aliphatic hydrocarbon ring), a group in which an alicyclic hydrocarbon group is bonded to the terminal of a linear or branched aliphatic hydrocarbon group, and a group in which an alicyclic hydrocarbon group is interposed in a linear or branched aliphatic hydrocarbon group. Examples of the linear or branched aliphatic hydrocarbon group include the same as those described above.

The number of carbon atoms in the above-described alicyclic hydrocarbon group is preferably 3 to 20 and more preferably 3 to 12.

The alicyclic hydrocarbon group may be a polycyclic group or a monocyclic group. As the monocyclic alicyclic hydrocarbon group, a group formed by removing two hydrogen atoms from a monocycloalkane is preferable. The number of carbon atoms in the monocycloalkane is preferably 3 to 6, and specific examples thereof include cyclopentane and cyclohexane.

As the polycyclic alicyclic hydrocarbon group, a group formed by removing two hydrogen atoms from a polycycloalkane is preferable. The number of carbon atoms in the polycycloalkane is preferably 7 to 12, and specific examples thereof include adamantane, norbornane, isobornane, tricyclodecane, and tetracyclododecane.

The aromatic hydrocarbon group in the divalent hydrocarbon group is a hydrocarbon group having at least one aromatic ring. The aromatic ring is not particularly limited as long as the aromatic ring has a cyclic conjugated system having (4n+2) pieces of 7 electrons, and may be monocyclic or polycyclic. The number of carbon atoms in the aromatic ring is preferably 5 to 30, more preferably 5 to 20, still more preferably 6 to 15, and particularly preferably 6 to 12. Specific examples of the aromatic ring include an aromatic hydrocarbon ring such as benzene, naphthalene, anthracene, and phenanthrene; and an aromatic heterocyclic ring in which some carbon atoms constituting the aromatic hydrocarbon ring are replaced with hetero atoms. Examples of the hetero atom in the aromatic heterocyclic ring include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) formed by removing two hydrogen atoms from the aromatic hydrocarbon ring or the aromatic heterocyclic ring; a group formed by removing two hydrogen atoms from an aromatic compound (biphenyl, fluorene, or the like) having two or more aromatic rings; and a group (a group in which one hydrogen atom is further removed from an aryl group in an arylalkyl group such as a benzyl group, a phenethyl group, a 1-naphthylmethyl group, a 2-naphthylmethyl group, a 1-naphthylethyl group, and a 2-naphthylethyl group) in which one hydrogen atom of a group (an aryl group or a heteroaryl group) formed by removing one hydrogen atom from the aromatic hydrocarbon ring or the aromatic heterocyclic ring is replaced with an alkylene group. The number of carbon atoms in the alkylene group which is bonded to the above-described aryl group or heteroaryl group is preferably 1 to 4, more preferably 1 or 2, and particularly preferably 1.

The divalent hydrocarbon group may have a substituent.

The linear or branched aliphatic hydrocarbon group as the divalent hydrocarbon group may or may not have a substituent. Examples of the substituent include a fluorine atom, a fluorinated alkyl group having 1 to 5 carbon atoms which is substituted with a fluorine atom, and a carbonyl group.

The alicyclic hydrocarbon group in the aliphatic hydrocarbon group including a ring in the structure thereof, as the divalent hydrocarbon group, may or may not have a substituent. Examples of the substituent include an alkyl group, an alkoxy group, a halogen atom, a halogenated alkyl group, a hydroxyl group, and a carbonyl group.

As the alkyl group as the above-described substituent, an alkyl group having 1 to 5 carbon atoms is preferable, and a methyl group, an ethyl group, a propyl group, an n-butyl group, or a tert-butyl group is most preferable.

As the alkoxy group as the above-described substituent, an alkoxy group having 1 to 5 carbon atoms is preferable, a methoxy group, an ethoxy group, an n-propoxy group, an iso-propoxy group, an n-butoxy group, or a tert-butoxy group is preferable, and a methoxy group or an ethoxy group is most preferable.

Examples of the halogen atom as the above-described substituent include a fluorine atom, a chlorine atom, a bromine atom, and an iodine atom. Among these, a fluorine atom is preferable.

Examples of the halogenated alkyl group as the above-described substituent include a group in which some or all hydrogen atoms in the alkyl group are replaced with the halogen atoms.

In the alicyclic hydrocarbon group, some carbon atoms constituting the ring structure thereof may be replaced with substituents having a hetero atom. As the substituent having a hetero atom, —O—, —C(═O)—O—, —S—, —S(═O)₂—, or —S(═O)₂—O— is preferable.

In the aromatic hydrocarbon group as the divalent hydrocarbon group, a hydrogen atom in the aromatic hydrocarbon group may be replaced with a substituent. For example, the hydrogen atom bonded to the aromatic ring in the aromatic hydrocarbon group may be replaced with a substituent. Examples of the substituent include an alkyl group, an alkoxy group, a halogen atom, a halogenated alkyl group, and a hydroxyl group.

As the alkyl group as the above-described substituent, an alkyl group having 1 to 5 carbon atoms is preferable, and a methyl group, an ethyl group, a propyl group, an n-butyl group, or a tert-butyl group is most preferable.

Examples of the alkoxy group, the halogen atom, and the halogenated alkyl group as the above-described substituent include the same as exemplary examples of the substituent which replaces the hydrogen atom in the alicyclic hydrocarbon group.

Regarding divalent linking group including hetero atom:

the hetero atom in the divalent linking group including a hetero atom is an atom other than a carbon atom and a hydrogen atom, and examples thereof include an oxygen atom, a nitrogen atom, a sulfur atom, and a halogen atom.

in the divalent linking group including a hetero atom, preferred examples of the linking group include —O—, —C(═O)—O—, —C(═O)—, —O—C(═O)—O—; —C(═O)—NH—, —NH—, —NH—C(═O)—O—, —NH—C(═NH)— (H may be replaced with a substituent such as an alkyl group, an acyl group, and the like); —S—, —S(═O)₂—, —S(═O)₂—O—, and a group represented by Formulae —Y^{2′}—O—Y²²—, —Y²¹—O—, —Y²¹—C(═O)—O—, —C(═O)—O—Y²¹, —[Y²¹—C(═O)—O]_{m″}—Y²²—, or —Y²¹—O—C(═O)—Y²²— [in the formulae, Y²¹ and Y²² each independently represent a divalent hydrocarbon group which may have a substituent, 0 represents an oxygen atom, and m″ represents an integer of 0 to 3].

In a case where the divalent linking group including a hetero atom is —C(═O)—NH—, —NH—, —NH—C(═O)—O—, or —NH—C(═NH)—, H may be replaced with a substituent such as an alkyl group, acyl, and the like. The substituent (alkyl group, acyl group, and the like) preferably has 1 to 10 carbon atoms, more preferably has 1 to 8 carbon atoms, and particularly preferably has 1 to 5 carbon atoms.

In Formulae —Y²¹—O—Y²²—, —Y²¹—O—, —Y²¹—C(═O)—O—, —C(═O)—O—Y²¹—, —[Y²¹—C(═O)—O]ₘ, —Y²—, or —Y²¹—O—C(═O)—Y²²—, Y²¹ and Y²² each independently represent a divalent hydrocarbon group which may have a substituent. Examples of the divalent hydrocarbon group include the same groups as those described above as the “divalent hydrocarbon group which may have a substituent” in the definition of the above-described divalent linking group.

As Y²¹, a linear aliphatic hydrocarbon group is preferable, a linear alkylene group is more preferable, a linear alkylene group having 1 to 5 carbon atoms is still more preferable, and a methylene group or an ethylene group is particularly preferable.

As Y²², a linear or branched aliphatic hydrocarbon group is preferable, and a methylene group, an ethylene group, or an alkylmethylene group is more preferable. The alkyl group in the alkylmethylene group is preferably a linear alkyl group having 1 to 5 carbon atoms, more preferably a linear alkyl group having 1 to 3 carbon atoms, and most preferably a methyl group.

In the group represented by the formula —[Y²—C(═O)—O]_{m″}—Y²²—, m″ is an integer of 0 to 3, preferably an integer of 0 to 2, more preferably 0 or 1, and particularly preferably 1. That is, it is particularly preferable that the group represented by the formula —[Y²¹—C(═O)—O]_{m″}—Y²²— is a group represented by formula —Y²¹—C(═O)—O—Y²²—. Among these, a group represented by formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

Among these, a glycidyl group is preferable as the epoxy group-containing group in R^{EP}.

Further, suitable examples of the novolak type epoxy resin (Anv) include a resin having a constitutional unit represented by Formula (anv1).

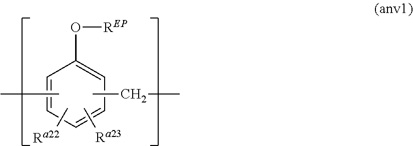

[in the formula, R^{EP} represents an epoxy group-containing group, and R^{a22} and R^{a23} each independently represent a hydrogen atom, an alkyl group having 1 to 5 carbon atoms, or a halogen atom]

In Formula (anv1), the alkyl group having 1 to 5 carbon atoms as R^{a22} and R^{a23} has the same definition as the alkyl group having 1 to 5 carbon atoms as R^{p1} and R^{p2} in Formula (A1). It is preferable that the halogen atom as R^{a22} and R^{a23} is a chlorine atom or a bromine atom.

In Formula (anv1), R^{EP} has the same definition as that for R^{EP} in Formula (A1), and it is preferable that R^{EP} represents a glycidyl group.

Specific examples of the constitutional unit represented by Formula (anv1) are shown below.

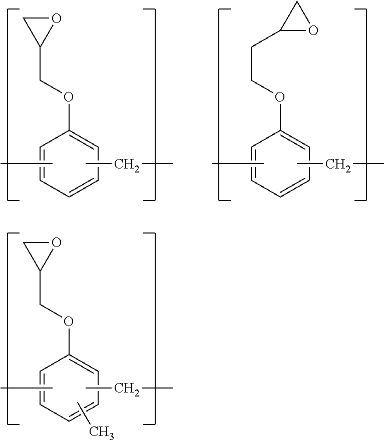

The novolak type epoxy resin (Anv) may be a resin consisting of only the above-described constitutional unit (anv1) or a resin having the constitutional unit (anv1) and other constitutional units. Examples of the other constitutional units include constitutional units represented by Formulae (anv2) and (anv3).

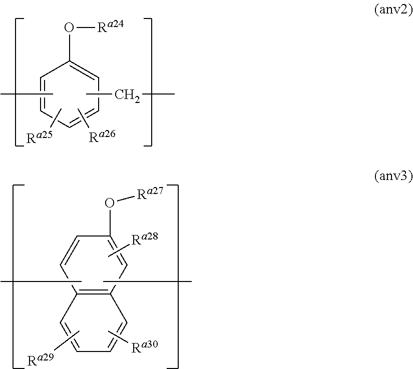

[in the formula, R^{a24} represents a hydrocarbon group which may have a substituent, R^{a25}, R^{a26}, and R^{a28} to R^{a30} each independently represent a hydrogen atom, an alkyl group having 1 to 5 carbon atoms, or a halogen atom, and R^{a27} represents an epoxy group-containing group or a hydrocarbon group which may have a substituent]

In Formula (anv2), R^{a24} is a hydrocarbon group which may have a substituent. Examples of the hydrocarbon group which may have a substituent include a linear or branched alkyl group and a cyclic hydrocarbon group.

The linear alkyl group preferably has 1 to 5 carbon atoms, more preferably has 1 to 4 carbon atoms, and still more preferably has 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group preferably has 3 to 10 carbon atoms and more preferably has 3 to 5 carbon atoms. Specific examples thereof include an isopropyl group, an isobutyl group, a tert-butyl group, an isopentyl group, a neopentyl group, an 1,1-diethylpropyl group, and a 2,2-dimethylbutyl group. Among these, an isopropyl group is preferable.

In a case where R¹²⁴ is a cyclic hydrocarbon group, the cyclic hydrocarbon group may be an aliphatic hydrocarbon group or an aromatic hydrocarbon group, and may be a polycyclic group or a monocyclic group.

As the aliphatic hydrocarbon group which is a monocyclic group, a group formed by removing one hydrogen atom from a monocycloalkane is preferable. The number of carbon atoms in the monocycloalkane is preferably 3 to 6, and specific examples thereof include cyclopentane and cyclohexane.

As the aliphatic hydrocarbon group which is a polycyclic group, a group formed by removing one hydrogen atom from a polycycloalkane is preferable. The number of carbon atoms in the polycycloalkane is preferably 7 to 12, and specific examples thereof include adamantane, norbornane, isobornane, tricyclodecane, and tetracyclododecane.

In a case where the cyclic hydrocarbon group as R^{a24} is an aromatic hydrocarbon group, the aromatic hydrocarbon group is a hydrocarbon group having at least one aromatic ring.

The aromatic ring is not particularly limited as long as the aromatic ring has a cyclic conjugated system having (4n+2) pieces of π electrons, and may be monocyclic or polycyclic. The number of carbon atoms in the aromatic ring is preferably 5 to 30, more preferably 5 to 20, still more preferably 6 to 15, and particularly preferably 6 to 12. Specific examples of the aromatic ring include an aromatic hydrocarbon ring such as benzene, naphthalene, anthracene, and phenanthrene; and an aromatic heterocyclic ring in which some carbon atoms constituting the aromatic hydrocarbon ring are replaced with hetero atoms. Examples of the hetero atom in the aromatic heterocyclic ring include an oxygen atom, a sulfur atom, and a nitrogen atom. Specific examples of the aromatic heterocyclic ring include a pyridine ring and a thiophene ring.

Specific examples of the aromatic hydrocarbon group in R^{a24} include a group (an aryl group or a heteroaryl group) formed by removing one hydrogen atom from the aromatic hydrocarbon ring or aromatic heterocyclic ring; a group formed by removing one hydrogen atom from an aromatic compound (biphenyl, fluorene, or the like) having two or more aromatic rings; and a group (for example, an arylalkyl group such as a benzyl group, a phenethyl group, a 1-naphthylmethyl group, a 2-naphthylmethyl group, a 1-naphthylethyl group, and a 2-naphthylethyl group) in which one hydrogen atom in an aromatic hydrocarbon ring or aromatic heterocyclic ring is replaced with an alkylene group. The number of carbon atoms in the alkylene group which is bonded to the aromatic hydrocarbon ring or the aromatic heterocyclic ring is preferably 1 to 4, more preferably 1 or 2, and particularly preferably 1.

In Formulae (anv2) and (anv3), R^{a25} and R^{a21}, and R^{a28} to R^{a30} each independently represent a hydrogen atom, an alkyl group having 1 to 5 carbon atoms, or a halogen atom, and the alkyl group having 1 to 5 carbon atoms and the halogen atom each have the same definition as that for R^{a22} and R^{a23}.

In Formula (anv3), R^{a27} is an epoxy group-containing group or a hydrocarbon group which may have a substituent. The epoxy group-containing group as R^{a27} has the same definition as that for R^{EP} in Formula (A1), and the hydrocarbon group which may have a substituent as R^{a27} has the same definition as that for R^{a24}.

Specific examples of the constitutional units represented by Formulae (anv2) and (anv3) are shown below.

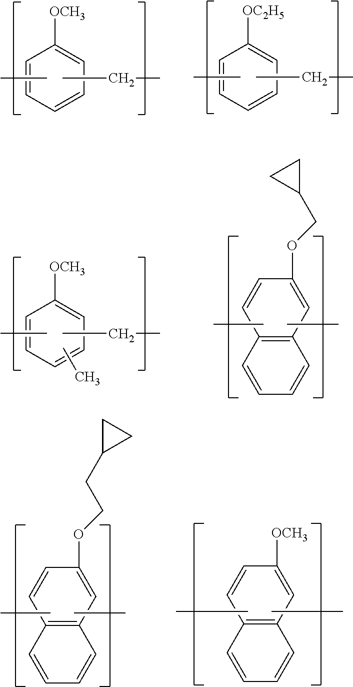

In a case where the novolak type epoxy resin (Anv) has other constitutional units in addition to the constitutional unit (anv1), the proportion of each constitutional unit in the resin (Anv) is not particularly limited, but the total amount of the constitutional units having an epoxy group is preferably 10 to 90 mol %, more preferably 20 to 80 mol %, and still more preferably 30 to 70 mol % with respect to the total amount of all constitutional units constituting the resin (Anv).

<<Bisphenol a Type Epoxy Resin (Abp)>>

Examples of the bisphenol A type epoxy resin (Abp) include an epoxy resin having a structure represented by Formula (abp1).

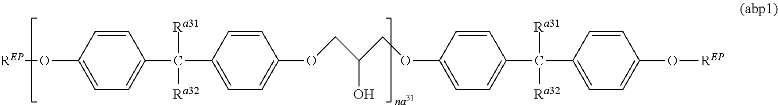

[in the formula, R^{EP} represents an epoxy group-containing group, R^{a31} and R^{a32} each independently represents a hydrogen atom or an alkyl group having 1 to 5 carbon atoms, and na³¹ represents an integer of 1 to 50]

In Formula (abp1), the alkyl group having 1 to 5 carbon atoms for R^{a31} and R^{a32} has the same definition as that for R^{p1} and R^{p2} in Formula (A1). Among the examples, it is preferable that R^{a31} and R^{a32} represent a hydrogen atom or a methyl group.

R^{EP} has the same definition as that for R^{EP} in Formula (A1), and it is preferable that R^{EP} represents a glycidyl group.

<<<Aliphatic Epoxy Resin and Acrylic Resin (Aac)>>

Examples of the aliphatic epoxy resin and the acrylic resin (Aac) include resins having an epoxy group-containing unit represented by Formulae (a1-1) and (a1-2).

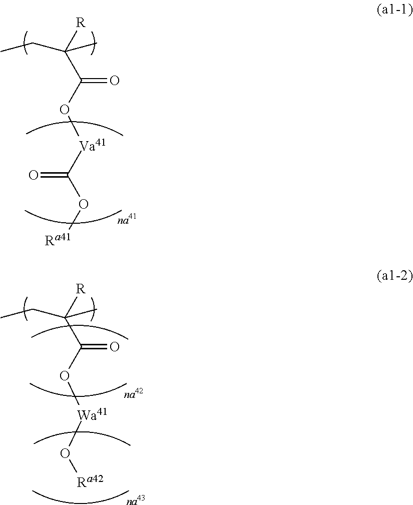

[in the formula, R represents a hydrogen atom, an alkyl group having 1 to 5 carbon atoms, or a halogenated alkyl group having 1 to 5 carbon atoms, Va⁴¹ represents a divalent hydrocarbon group which may have a substituent, na⁴¹ represents an integer of 0 to 2, R^{a41} and R^{a42} represent an epoxy group-containing group, na⁴² represents 0 or 1, Wa⁴¹ represents an (na⁴³+1)-valent aliphatic hydrocarbon group, and na⁴³ represents an integer of 1 to 3]

In Formula (a1-1), R represents a hydrogen atom, an alkyl group having 1 to 5 carbon atoms, or a halogenated alkyl group having 1 to 5 carbon atoms.

As the alkyl group having 1 to 5 carbon atoms as R, a linear or branched alkyl group is preferable, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R is a group in which some or all hydrogen atoms in the alkyl group having 1 to 5 carbon atoms are replaced with halogen atoms. Examples of the halogen atom include a fluorine atom, a chlorine atom, a bromine atom, and an iodine atom. Among these, a fluorine atom is particularly preferable.

As R, a hydrogen atom, an alkyl group having 1 to 5 carbon atoms, or a fluorinated alkyl group having 1 to 5 carbon atoms is preferable, and a hydrogen atom or a methyl group is most preferable from the viewpoint of industrial availability.

In Formula (a1-1), Va⁴¹ represents a divalent hydrocarbon group which may have a substituent, and examples thereof are the same as those for the divalent hydrocarbon group which may have a substituent, described in the section of R^{EP} in Formula (A1).

Among these, as the hydrocarbon group represented by Va⁴¹, an aliphatic hydrocarbon group is preferable, a linear or branched aliphatic hydrocarbon group is more preferable, a linear aliphatic hydrocarbon group is still more preferable, and a linear alkylene group is particularly preferable.

In Formula (a1-1), na⁴¹ represents an integer of 0 to 2 and preferably 0 or 1.

In Formulae (a1-1) and (a1-2), R^{a41} and R^{a42} represent an epoxy group-containing group and have the same definition as that for R^{EP} in Formula (A1).

In Formula (a1-2), the (na⁴³+1)-valent aliphatic hydrocarbon group in Wa⁴¹ indicates a hydrocarbon group with no aromaticity, and may be saturated or unsaturated. In general, it is preferable that the aliphatic hydrocarbon group is saturated. Examples of the aliphatic hydrocarbon group include a linear or branched aliphatic hydrocarbon group, an aliphatic hydrocarbon group having a ring in the structure thereof, and a group formed by combining a linear or branched aliphatic hydrocarbon group and an aliphatic hydrocarbon group having a ring in the structure thereof.

In Formula (a1-2), na⁴³ represents an integer of 1 to 3 and preferably 1 or 2.

Specific examples of the constitutional unit represented by Formula (a1-1) or (a1-2) are shown below.

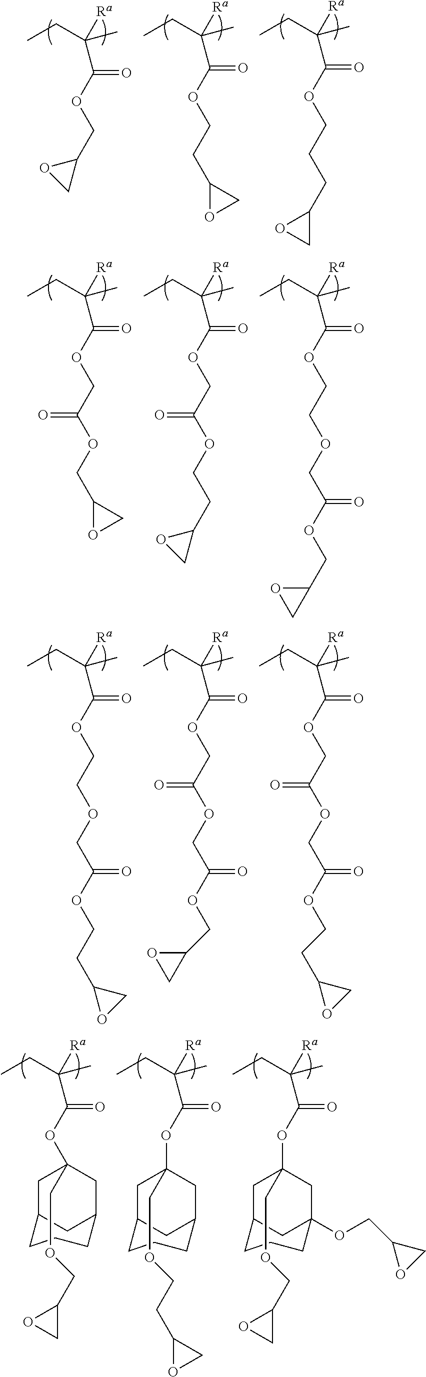

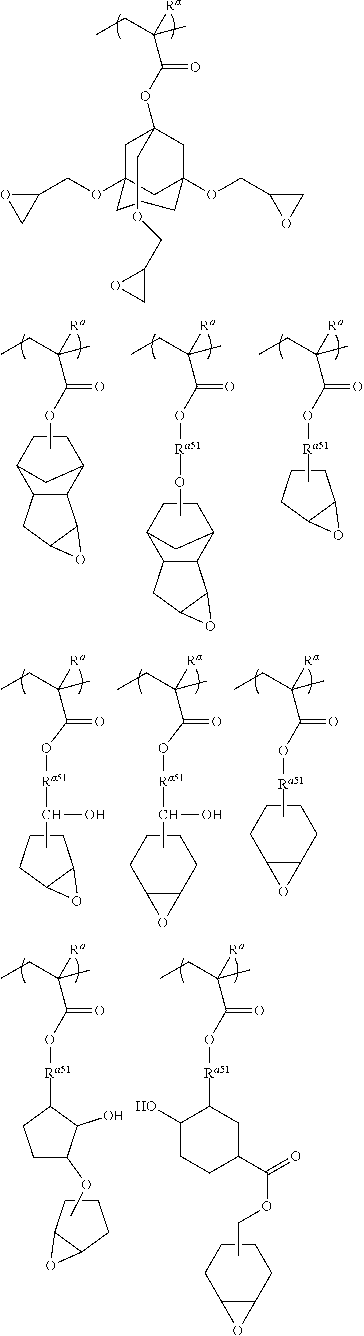

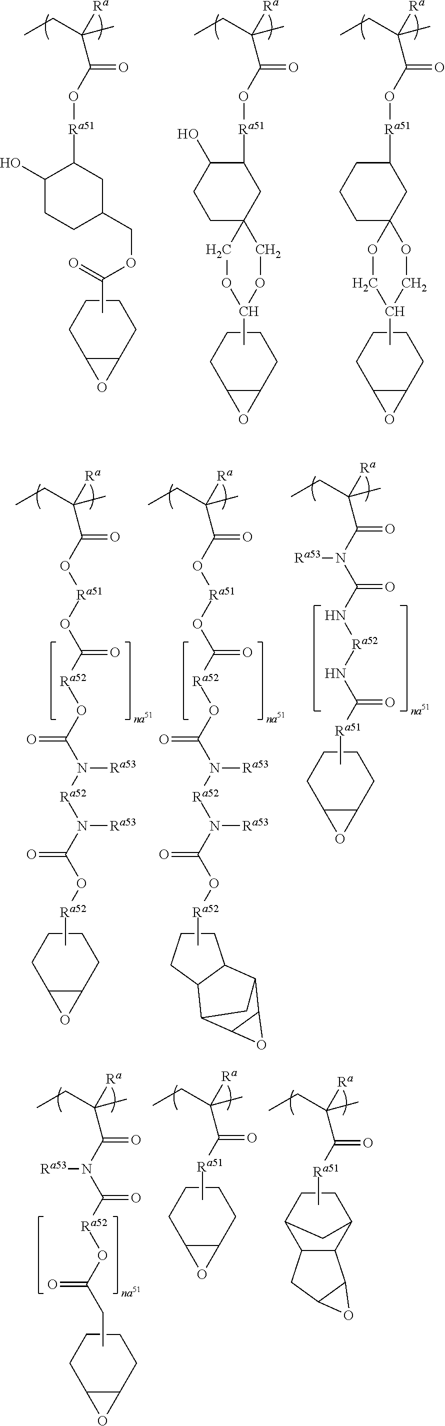

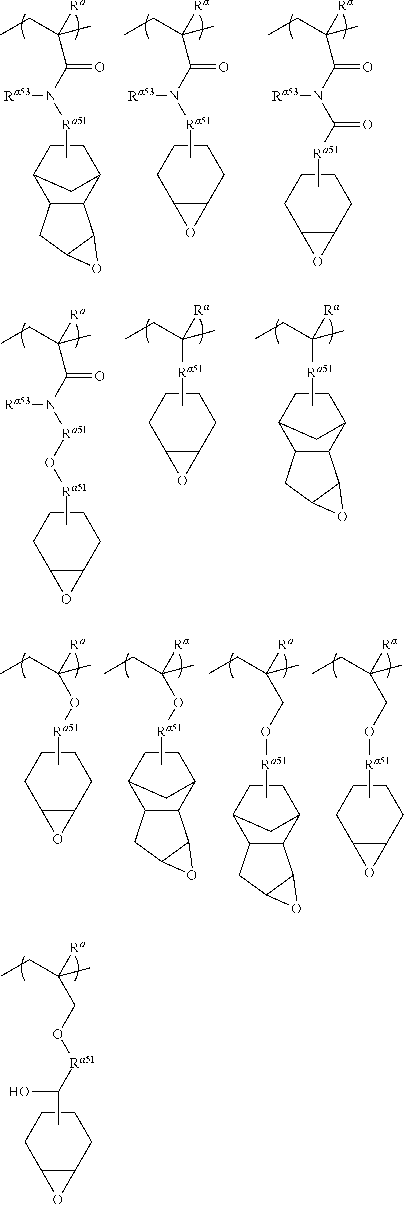

In the formulae, R^{a} represents a hydrogen atom, a methyl group, or a trifluoromethyl group.

R^{a51} represents a divalent hydrocarbon group having 1 to 8 carbon atoms. R^{a5} represents a divalent hydrocarbon group having 1 to 20 carbon atoms. R^{a53} represents a hydrogen atom or a methyl group. na⁵¹ represents an integer of 0 to 10.

R^{a51}, R^{a52}, and R^{a53} may be the same as or different from one another.

Further, the acrylic resin (Aac) may have a constitutional unit derived from other polymerizable compounds for the purpose of appropriately controlling the physical and chemical characteristics. Examples of such a polymerizable compound include known radical polymerizable compounds and anionic polymerizable compounds. Examples of such a polymerizable compound include monocarboxylic acids such as acrylic acid, methacrylic acid, and crotonic acid; dicarboxylic acids such as maleic acid, fumaric acid, and itaconic acid; methacrylic acid derivatives containing a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl (meth)acrylate, ethyl (meth)acrylate, and butyl (meth)acrylate; (meth)acrylic acid hydroxy alkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene, and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

In a case where the aliphatic epoxy resin and the acrylic resin (Aac) have other constitutional units, the content ratio of the epoxy group-containing unit in the resin is preferably 5 to 40 mol %, more preferably 10 to 30 mol %, and most preferably 15 to 25 mol %.

Further, suitable examples of the aliphatic epoxy resin also include a compound (hereinafter, also referred to as a “component (m1)”) having a partial structure represented by Formula (m1).

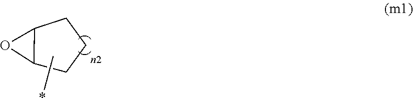

[in the formula, n₂ represents an integer of 1 to 4, and * represents a bonding site]

In Formula (m1), n₂ is an integer of 1 to 4, preferably an integer of 1 to 3, and more preferably 2.

Examples of the component (m1) include a compound in which a plurality of the partial structures represented by Formula (m1) described above are bonded through a divalent linking group or a single bond. Among these, a compound in which a plurality of the partial structures represented by Formula (m1) described above are bonded through a divalent linking group.

Here, the divalent linking group is not particularly limited, and suitable examples thereof include a divalent hydrocarbon group which may have a substituent and a divalent linking group including a hetero atom. The divalent hydrocarbon group which may have a substituent and the divalent linking group including a hetero atom are the same as the divalent hydrocarbon group which may have a substituent and the divalent linking group including a hetero atom, described in R^{EP} (epoxy group-containing group) in Formula (A1) described above. Among these, the divalent linking group including a hetero atom is preferable, and a group represented by —Y²¹—C(═O)—O— or a group represented by —C(═O)—O—Y²¹— is more preferable. As Y²¹, a linear aliphatic hydrocarbon group is preferable, a linear alkylene group is more preferable, a linear alkylene group having 1 to 5 carbon atoms is still more preferable, and a methylene group or an ethylene group is particularly preferable.

Furthermore, suitable examples of the aliphatic epoxy resin also include a compound (hereinafter, also referred to as a “component (m2)”) represented by Formula (m2).

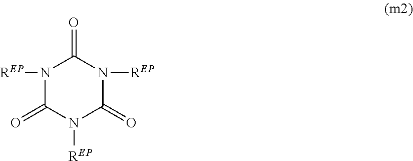

[in the formula, R^{EP} represents an epoxy group-containing group, and a plurality of R^{EP}'s may be the same as or different from one another]

In Formula (m2), R^{EP} represents an epoxy group-containing group and has the same definition as that for R^{EP} in Formula (A1).

The component (A) may be used alone or in combination of two or more kinds thereof.

It is preferable that the component (A) contains at least one resin selected from the group consisting of the novolak type epoxy resin (Anv), the bisphenol A type epoxy resin (Abp), a bisphenol F type epoxy resin, the aliphatic epoxy resin, and the acrylic resin (Aac).

Among these, it is more preferable that the component (A) includes at least one resin selected from the group consisting of the novolak type epoxy resin (Anv), the bisphenol A type resin (Abp), the aliphatic epoxy resin, and the acrylic resin (Aac).

Among these, it is still more preferable that the component (A) includes at least one resin selected from the group consisting of the novolak type epoxy resin (Anv), the aliphatic epoxy resin, and the acrylic resin (Aac), and it is particularly preferable that the component (A) includes two or more resins selected from the group consisting of the novolak type epoxy resin (Anv), the aliphatic epoxy resin, and the acrylic resin (Aac).

In a case where the component (A) is used in combination of two or more kinds thereof, from the viewpoint that film characteristics (rolling and laminating properties) are improved in a case where the photosensitive resist film is formed, it is preferable that the component (A) includes a combination of the novolak type epoxy resin (Anv) and the aliphatic epoxy resin.

Specific examples of such a combination include a combination of a component (A1) and at least one (hereinafter, referred to as a “component (m)”) selected from the group consisting of the component (m1) and the component (m2). Among these, a combination of the component (A1), the component (m1), and the component (m2) is most preferable.

In a case where the component (m1) and the component (m2) are included in combination, a ratio of the component (m1) to the component (m2), as a mass ratio represented by component (m1)/component (m2), is preferably 2/8 to 8/2, more preferably 3/7 to 7/3, and still more preferably 4/6 to 6/4. In a case where the mass ratio is within the above-described preferred range, the film characteristics (rolling and laminating properties) are further improved in a case where the photosensitive resist film is formed.

In particular, the component (A) contains the component (A1), the component (m1), and the component (m2), and from the viewpoints of the balance between the hardness and flexibility of the cured film, a total amount of the component (m1) and the component (m2) with respect to a total amount of the component (A1), the component (m1), and the component (m2) is preferably 15% by mass or more, more preferably 20% by mass or more, still more preferably 25% by mass or more, particularly preferably 25% by mass or more, and most preferably more than 25% by mass and 30% by mass or less.

The mass-average molecular weight of the component (A) in terms of polystyrene is preferably 100 to 300000, more preferably 200 to 200000, and still more preferably 300 to 200000. By setting the mass-average molecular weight to be in the above-described range, peeling from the support is less likely to occur, and the hardness of the cured film to be formed is sufficiently increased.

Further, the dispersity of the component (A) is preferably 1.05 or more. By setting the dispersity thereof to such a value, lithography characteristics in pattern formation are more improved.

The dispersity here indicates a value obtained by dividing the mass-average molecular weight by the number-average molecular weight.

Examples of commercially available products of the component (A) include, as novolak type epoxy resins (Anv), JER-152, JER-154, JER-157S70, and JER-157S65 (all manufactured by Mitsubishi Chemical Corporation), EPICLON N-740, EPICLON N-740, EPICLON N-770, EPICLON N-775, EPICLON N-660, EPICLON N-665, EPICLON N-670, EPICLON N-673, EPICLON N-680, EPICLON N-690, EPICLON N-695, and EPICLON HP5000 (all manufactured by DIC Corporation), and EOCN-1020 (manufactured by Nippon Kayaku Co., Ltd.).

Examples of commercially available products of the component (A) include, as bisphenol A type epoxy resins (Abp), JER-827, JER-828, JER-834, JER-1001, JER-1002, JER-1003, JER-1055, JER-1007, JER-1009, and JER-1010 (all manufactured by Mitsubishi Chemical Corporation), and EPICLON 860, EPICLON 1050, EPICLON 1051, and EPICLON 1055 (all manufactured by DIC Corporation).

Examples of commercially available products of the component (A) include, as bisphenol F type epoxy resins, JER-806, JER-807, JER-4004, JER-4005, JER-4007, and JER-4010 (all manufactured by Mitsubishi Chemical Corporation), EPICLON830 and EPICLON835 (both manufactured by DIC Corporation), and LCE-21 and RE-602S (both manufactured by Nippon Kayaku Co., Ltd.).

Examples of commercially available products of the component (A) include, as aliphatic epoxy resins, ADEKA RESIN EP-4080S, ADEKA RESIN EP-4085S, and ADEKA RESIN EP-4088S (all manufactured by ADEKA CORPORATION), CELLOXIDE 2021P, CELLOXIDE 2081, CELLOXIDE 2083, CELLOXIDE 2085, CELLOXIDE 8000, CELLOXIDE 8010, EHPE-3150, EPOLEAD PB 3600, and EPOLEAD PB4700 (all manufactured by Daicel Corporation), DENACOL EX-211L, EX-212L, EX-214L, EX-216L, EX-321L, and EX-850L (all manufactured by Nagase ChemteX Corporation), and TEPIC-VL (manufactured by Nissan Chemical Industries, Ltd.).

The content of the component (A) in the photosensitive composition according to the embodiment may be adjusted according to the film thickness and the like of the photosensitive resin film intended to be formed.

<Metal Oxide (M)>

In the photosensitive composition according to the present embodiment, by including a metal oxide (component (M)) in combination in addition to the component (A) and the component (I), a cured film with increased hardness can be obtained. In addition, a high-resolution pattern can be formed with a favorable shape.

Examples of the component (M) include oxides of metals such as silicon (metallic silicon), titanium, zirconium, and hafnium. Among these, an oxide of silicon is preferable. In addition, it is particularly preferable to use silica.

Further, it is preferable that the component (M) is particulate.

Such a particulate component (M) is formed of preferably a group consisting of particles having a volume average particle diameter of 5 to 40 nm, more preferably a group consisting of particles having a volume average particle diameter of 5 to 30 nm, and still more preferably a group consisting of particles having a volume average particle diameter of 10 to 20 nm.

In a case where the volume average particle diameter of the component (M) is greater than or equal to the lower limit value of the above-described preferred range, the hardness of the cured film is likely to be increased. On the other hand, in a case of being lower than or equal to the upper limit value of the above-described preferred range, residues are unlikely to be generated during pattern formation, and a pattern with higher resolution is easily formed.

The particle diameter of the component (M) may be appropriately selected according to the exposure light source. Typically, it is considered that particles having a particle diameter of 1/10 or less with respect to the wavelength of light are almost not affected by light scattering. Therefore, for example, in a case where a fine structure is formed by photolithography with i-rays (365 nm), it is preferable that a group (particularly preferably a group of silica particles) consisting of particles having a primary particle diameter (volume average value) of 10 to 20 nm is used as the component (M).

The component (M) may be used alone or in combination of two or more kinds thereof.

The content of the component (M) is preferably more than 30 parts by mass and 180 parts by mass or less, more preferably 40 to 170 parts by mass, and still more preferably 50 to 150 parts by mass with respect to 100 parts by mass of the component (A).

In a case where the content of the component (M) is more than the lower limit value of the above-described preferred range, the hardness of the cured film is further increased. On the other hand, in a case of being lower than or equal to the upper limit value of the above-described preferred range, fluidity of the photosensitive composition is easily maintained.

<Cationic Polymerization Initiator (I)>

The cationic polymerization initiator (component (I)) is a compound capable of generating a cation by being irradiated with active energy rays such as ultraviolet rays, far ultraviolet rays, excimer laser light of KrF, ArF, and the like, X rays, and electron beams, and the cation becoming a polymerization initiator.

The component (I) in the photosensitive composition according to the present embodiment is not particularly limited, and examples thereof include a compound represented by Formula (I1) (hereinafter, referred to as a “component (I1)”), a compound represented by Formula (I2) (hereinafter, referred to as a “component (I2)”), and a compound represented by Formula (I3-1) or (I3-2) (hereinafter, referred to as a “component (I3)”).

Among these, since relatively strong acids are generated upon exposure from both of the component (I1) and the component (I2), in a case where a pattern is formed using a photosensitive composition which contains the component (I), sufficient sensitivity is obtained so that a favorable pattern is formed.

<<Component (I1)>>

The component (I1) is a compound represented by Formula (I1).

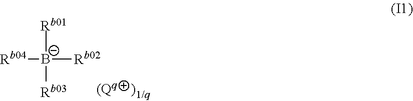

[in the formula, R^{b01} to R^{b04} each independently represent an aryl group which may have a substituent, or a fluorine atom, q represents an integer of 1 or more, and Q^{q+}'s each independently represent a q-valent organic cation]

Anion Moiety

In Formula (I1), R^{b01} to R^{b04} each independently represent an aryl group which may have a substituent or a fluorine atom.

The aryl group in R^{b01} to R^{b04} preferably has 5 to 30 carbon atoms, more preferably has 5 to 20 carbon atoms, still more preferably has 6 to 15 carbon atoms, and particularly preferably has 6 to 12 carbon atoms. Specific examples thereof include a naphthyl group, a phenyl group, and an anthracenyl group. Among these, a phenyl group is preferable from the viewpoint of availability.

The aryl group in R^{b01} to R^{b04} may have a substituent. The substituent is not particularly limited. As the substituent, a halogen atom, a hydroxyl group, an alkyl group (preferably a linear or branched alkyl group having 1 to 5 carbon atoms), or a halogenated alkyl group is preferable, a halogen atom or a halogenated alkyl group having 1 to 5 carbon atoms is more preferable, and a fluorine atom or a fluorinated alkyl group having 1 to 5 carbon atoms is particularly preferable. It is preferable that the aryl group has a fluorine atom because the polarity of the anion moiety is increased.

Among these, R^{b01} to R^{b04} in Formula (I1) each represent preferably a fluorinated phenyl group and particularly preferably a perfluorophenyl group.

Specific preferred examples of the anion moiety of the compound represented by Formula (I1) include tetrakis(pentafluorophenyl)borate ([B(C₆F₅)₄]⁻); tetrakis[(trifluoromethyl)phenyl]borate ([B(C₆H₄CF₃)₄]⁻); difluorobis(pentafluorophenyl)borate ([(C₆F₅)₂BF₂]⁻); trifluoro(pentafluorophenyl)borate ([(C₆F₅)BF₃]⁻); and tetrakis(difluorophenyl)borate ([B(C₆H₃F₂)₄]⁻).

Among these, tetrakis(pentafluorophenyl)borate ([B(C₆F₅)₄]⁻) is particularly preferable.

Cation Moiety

In Formula (I1), q represents an integer of 1 or more. Q^{q+}'s each independently represent a q-valent organic cation.

Suitable examples of Q^{q+} include a sulfonium cation and an iodonium cation. Further, organic cations represented by Formulae (ca-1) to (ca-5) are particularly preferable.

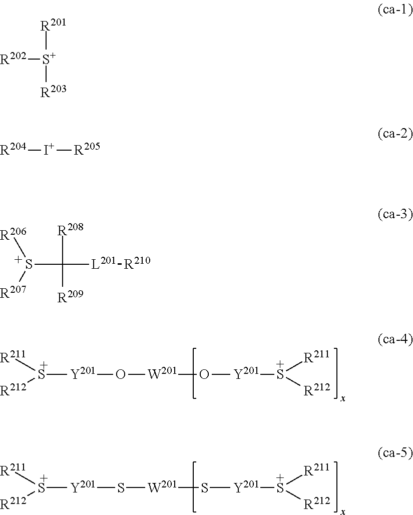

[in the formulae, R²⁰¹ to R²⁰⁷, R²¹¹, and R²¹² each independently represent an aryl group which may have a substituent, a heteroaryl group, an alkyl group, or an alkenyl group, R²⁰¹ to R²⁰³, R²⁰⁶ and R²⁰⁷, and R²¹¹ and R²¹² may be bonded to one another to form a ring together with a sulfur atom in the formulae, R²⁰⁸ and R²⁰⁹ each independently represent a hydrogen atom or an alkyl group having 1 to 5 carbon atoms, R²¹⁰ represents an aryl group which may have a substituent, an alkyl group which may have a substituent, an alkenyl group which may have a substituent, or a —SO₂-containing cyclic group which may have a substituent, L²⁰¹ represents —C(═O)— or —C(═O)—O—, Y²⁰¹'s each independently represent an arylene group, an alkylene group, or an alkenylene group, x represents 1 or 2, and W²⁰¹ represents an (x+1)-valent linking group]

Examples of the aryl group in R²⁰¹ to R²⁰⁷, and R²¹¹ and R²¹² include an unsubstituted aryl group having 6 to 20 carbon atoms. Among these, a phenyl group or a naphthyl group is preferable.

Examples of the heteroaryl group in R²⁰¹ to R²⁰⁷, and R²¹¹ and R²¹² include those in which some carbon atoms constituting the aryl group are substituted with a hetero atom. Examples of the hetero atom include an oxygen atom, a sulfur atom, and a nitrogen atom. Examples of the heteroaryl group include a group formed by removing one hydrogen atom from 9H-thioxanthene, and examples of the substituted heteroaryl group include a group formed by removing one hydrogen atom from 9H-thioxanthene-9-one.

As the alkyl group in R²⁰¹ to R²⁰⁷, and R²¹¹ and R²¹², a chain-like or cyclic alkyl group having 1 to 30 carbon atoms is preferable.

As the alkenyl group in R²⁰¹ to R²⁰⁷, and R²¹¹ and R²¹², an alkenyl group having 2 to 10 carbon atoms is preferable.

Examples of the substituent which may be included in R²⁰¹ to R²⁰⁷, and R²¹⁰ to R²¹² include an alkyl group, a halogen atom, a halogenated alkyl group, a carbonyl group, a cyano group, an amino group, an oxo group (═O), an aryl group, and groups represented by Formulae (ca-r-1) to (ca-r-10).

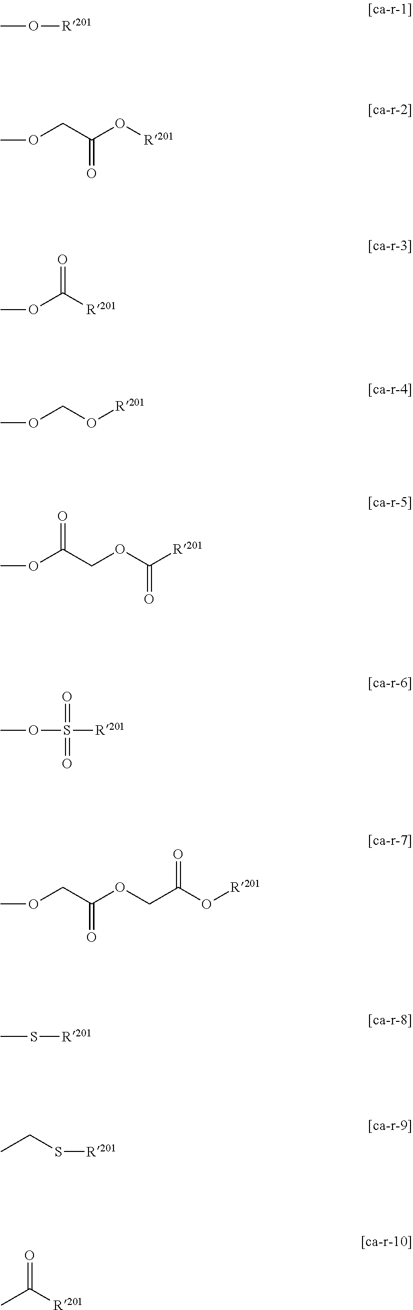

[in the formulae, R′²⁰¹'s each independently represent a hydrogen atom, a cyclic group which may have a substituent, a chain-like alkyl group which may have a substituent, or a chain-like alkenyl group which may have a substituent.]

In Formulae (ca-r-1) to (ca-r-10), R′²⁰¹'s each independently represent a hydrogen atom, a cyclic group which may have a substituent, a chain-like alkyl group which may have a substituent, or a chain-like alkenyl group which may have a substituent.

Cyclic group which may have substituent:

It is preferable that the cyclic group is a cyclic hydrocarbon group, and the cyclic hydrocarbon group may be an aromatic hydrocarbon group or a cyclic aliphatic hydrocarbon group. The aliphatic hydrocarbon group indicates a hydrocarbon group with no aromaticity. Further, the aliphatic hydrocarbon group may be saturated or unsaturated. In general, it is preferable that the aliphatic hydrocarbon group is saturated.

The aromatic hydrocarbon group in R′²⁰¹ is a hydrocarbon group having an aromatic ring. The number of carbon atoms in the aromatic hydrocarbon group is preferably 3 to 30, more preferably 5 to 30, still more preferably 5 to 20, particularly preferably 6 to 15, and most preferably 6 to 10. Here, the number of carbon atoms thereof does not include the number of carbon atoms in a substituent.

Specific examples of the aromatic ring contained in the aromatic hydrocarbon group in R′²⁰¹ include benzene, fluorene, naphthalene, anthracene, phenanthrene, biphenyl, an aromatic heterocyclic ring in which some carbon atoms constituting any of these aromatic rings are substituted with hetero atom, and a ring in which some hydrogen atoms constituting any of these aromatic rings or aromatic heterocyclic rings are substituted with an oxo group. Examples of the hetero atom in the aromatic heterocyclic ring include an oxygen atom, a sulfur atom, and a nitrogen atom.

Specific examples of the aromatic hydrocarbon group in R′²⁰¹ include a group (an aryl group such as a phenyl group, a naphthyl group, or an anthracenyl group) formed by removing one hydrogen atom from the aromatic ring; a group (an arylalkyl group such as a benzyl group, a phenethyl group, a 1-naphthylmethyl group, a 2-naphthylmethyl group, a 1-naphthylethyl group, and a 2-naphthylethyl group, and the like) in which one hydrogen atom in the aromatic ring is replaced with an alkylene group; a group formed by removing one hydrogen atom from a ring (such as anthraquinone) in which some hydrogen atoms constituting the aromatic ring is replaced with an oxo group and the like; and a group formed by removing one hydrogen atom from an aromatic heterocyclic ring (such as 9H-thioxanthene or 9H-thioxanthen-9-one). The alkylene group (an alkyl chain in the arylalkyl group) preferably has 1 to 4 carbon atoms, more preferably has 1 or 2 carbon atoms, and particularly preferably has 1 carbon atom.

Examples of the cyclic aliphatic hydrocarbon group in R′²⁰¹ include an aliphatic hydrocarbon group containing a ring in the structure thereof.

Examples of the aliphatic hydrocarbon group containing a ring in the structure thereof include an alicyclic hydrocarbon group (a group formed by removing one hydrogen atom from an aliphatic hydrocarbon ring), a group in which an alicyclic hydrocarbon group is bonded to the terminal of a linear or branched aliphatic hydrocarbon group, and a group in which an alicyclic hydrocarbon group is interposed in a linear or branched aliphatic hydrocarbon group.

The number of carbon atoms in the alicyclic hydrocarbon group is preferably 3 to 20 and more preferably 3 to 12.

The alicyclic hydrocarbon group may be a monocyclic group or a polycyclic group. As the monocyclic alicyclic hydrocarbon group, a group formed by removing one or more hydrogen atoms from a monocycloalkane is preferable. The number of carbon atoms in the monocycloalkane is preferably 3 to 6, and specific examples thereof include cyclopentane and cyclohexane. As the polycyclic alicyclic hydrocarbon group, a group formed by removing one or more hydrogen atoms from a polycycloalkane is preferable, and the number of carbon atoms in the polycycloalkane is preferably 7 to 30. Among polycycloalkanes, a polycycloalkane having a bridged ring polycyclic skeleton, such as adamantane, norbornane, isobornane, tricyclodecane, or tetracyclododecane, and a polycycloalkane having a fused ring polycyclic skeleton, such as a cyclic group having a steroid skeleton are more preferable.

Among these examples, as the cyclic aliphatic hydrocarbon group in R′²⁰¹, a group formed by removing one or more hydrogen atoms from a monocycloalkane or a polycycloalkane is preferable, a group formed by removing one hydrogen atom from a polycycloalkane is more preferable, an adamantyl group or a norbornyl group is particularly preferable, and an adamantyl group is most preferable.

The number of carbon atoms in the linear or branched aliphatic hydrocarbon group which may be bonded to the alicyclic hydrocarbon group is preferably 1 to 10, more preferably 1 to 6, still more preferably 1 to 4, and most preferably 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable. Specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Chain-like alkyl group which may have substituent:

the chain-like alkyl group as R′²⁰¹ may be linear or branched.

The linear alkyl group preferably has 1 to 20 carbon atoms, more preferably has 1 to 15 carbon atoms, and most preferably has 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group.

The branched alkyl group preferably has 3 to 20 carbon atoms, more preferably has 3 to 15 carbon atoms, and most preferably has 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

the chain-like alkenyl group as R′²⁰¹ may be linear or branched, and the number of carbon atoms in the chain-like alkenyl group is preferably 2 to 10, more preferably 2 to 5, still more preferably 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group. Among the examples, as the chain-like alkenyl group, a linear alkenyl group is preferable, a vinyl group or a propenyl group is more preferable, and a vinyl group is particularly preferable.

Examples of the substituent in the cyclic group, the chain-like alkyl group, or the chain-like alkenyl group as R′²⁰¹ include an alkoxy group, a halogen atom, a halogenated alkyl group, a hydroxyl group, a carbonyl group, a nitro group, an amino group, an oxo group, the cyclic group in R′²⁰¹, an alkylcarbonyl group, and a thienylcarbonyl group.

Among these, it is preferable that R′²⁰¹ represents a cyclic group which may have a substituent or a chain-like alkyl group which may have a substituent.

In a case where R²⁰¹ to R²⁰³, R²⁰⁶ and R²⁰⁷, and R²¹¹ and R²¹² are bonded to one another to form a ring together with the sulfur atom in the formula, these groups may be bonded to one another through a hetero atom such as a sulfur atom, an oxygen atom, or a nitrogen atom, or a functional group such as a carbonyl group, —SO—, —SO₂—, —SO₃—, —COO—, —CONH—, or —N(R_{N})— (here, R_{N} represents an alkyl group having 1 to 5 carbon atoms). As a ring to be formed, one ring containing the sulfur atom in the formula in the ring skeleton thereof is preferably a 3- to 10-membered ring and particularly preferably a 5- to 7-membered ring, including the sulfur atom. Specific examples of the ring to be formed include a thiophene ring, a thiazole ring, a benzothiophene ring, a thianthrene ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

In Formula (ca-3), R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ each represent an alkyl group, R²⁰⁸ and R²⁰⁹ may be bonded to each other to form a ring.

In Formula (ca-3), R²¹⁰ represents an aryl group which may have a substituent, an alkyl group which may have a substituent, an alkenyl group which may have a substituent, or a —SO₂-containing cyclic group which may have a substituent.

Examples of the aryl group in R²¹⁰ include an unsubstituted aryl group having 6 to 20 carbon atoms, and a phenyl group or a naphthyl group is preferable.

As the alkyl group in R²¹⁰, a chain-like or cyclic alkyl group having 1 to 30 carbon atoms is preferable.

The number of carbon atoms in the alkenyl group in R²¹⁰ is preferably 2 to 10.

In Formulae (ca-4) and (ca-5), Y²⁰¹'s each independently represent an arylene group, an alkylene group, or an alkenylene group.

Examples of the arylene group in Y²⁰¹ include a group formed by removing one hydrogen atom from an aryl group of exemplary examples as the aromatic hydrocarbon group in R′²⁰¹.

Examples of the alkylene group and alkenylene group in Y²⁰¹ include a group formed by removing one hydrogen atom from a group of exemplary examples as the chain-like alkyl group or the chain-like alkenyl group in R′²⁰¹.

In Formulae (ca-4) and (ca-5), x represents 1 or 2.

W²⁰¹ represents an (x+1)-valent linking group, that is, a divalent or trivalent linking group.

As the divalent linking group in W²⁰¹, a divalent hydrocarbon group which may have a substituent is preferable. Further, the same divalent hydrocarbon groups which may have a substituent as exemplary examples in the section of R^{EP} in Formula (A1) are preferable. The divalent linking group in W²⁰¹ may be linear, branched, or cyclic, and a cyclic divalent linking group is preferable. Among these, a group formed by combining two carbonyl groups at both ends of an arylene group or a group formed of only an arylene group is preferable. Examples of the arylene group include a phenylene group and a naphthylene group. Among these, a phenylene group is particularly preferable.

Examples of the trivalent linking group in W²⁰¹ include a group formed by removing one hydrogen atom from the divalent linking group in W²⁰¹ and a group in which the divalent linking group is bonded to the divalent linking group. As the trivalent linking group in W²⁰¹, a group in which two carbonyl groups are bonded to an arylene group is preferable.

Specific suitable examples of the cation represented by Formula (ca-1) include cations represented by Formulae (ca-1-1) to (ca-1-24).

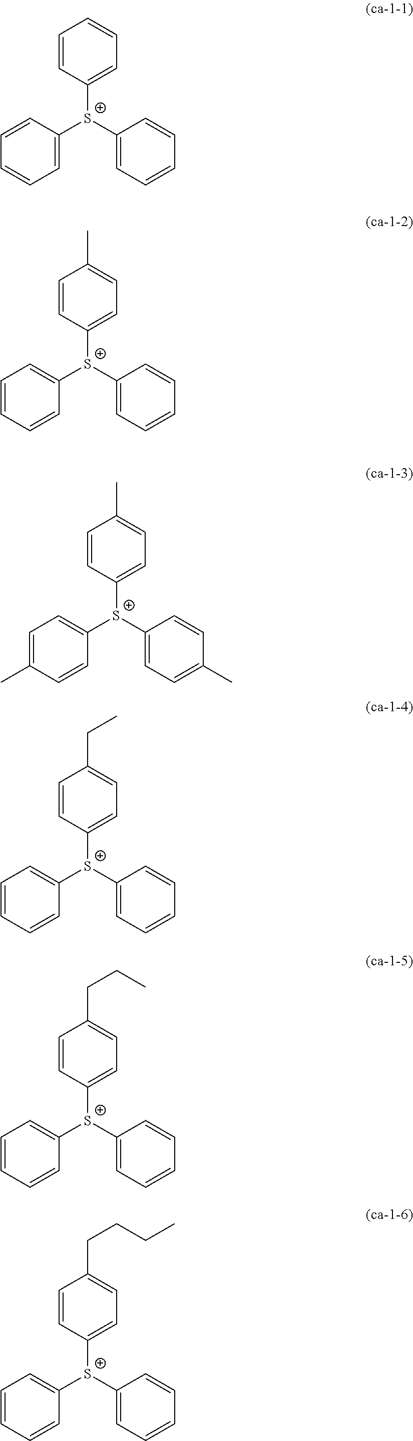

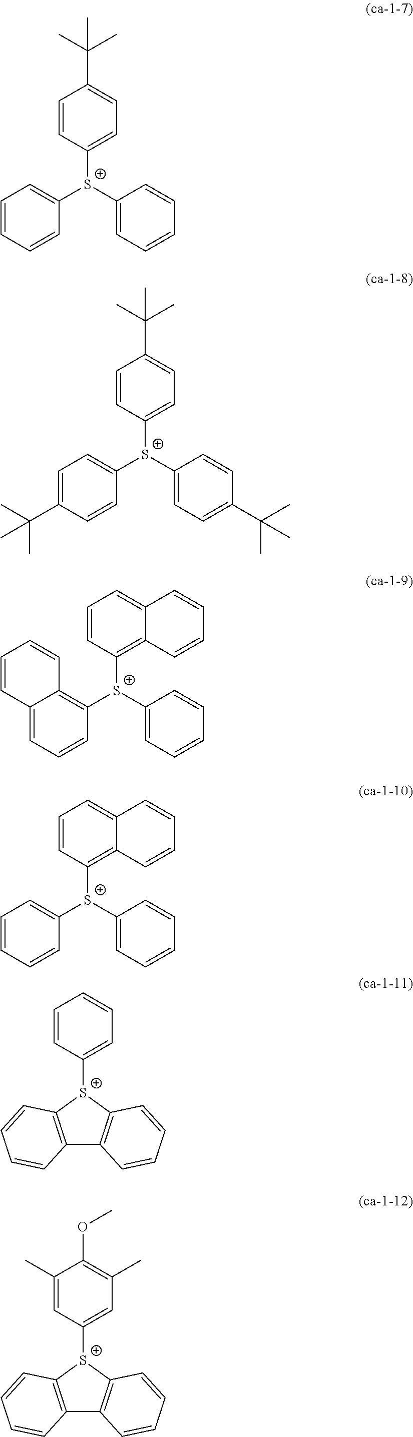 [SMILES: CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; c1ccc([S+](c2cccc3ccccc23)c2cccc3ccccc23)cc1 ; c1ccc([S+](c2ccccc2)c2cccc3ccccc23)cc1 ; c1ccc(-[s+]2c3ccccc3c3ccccc32)cc1 ; COc1c(C)cc(-[s+]2c3ccccc3c3ccccc32)cc1C]

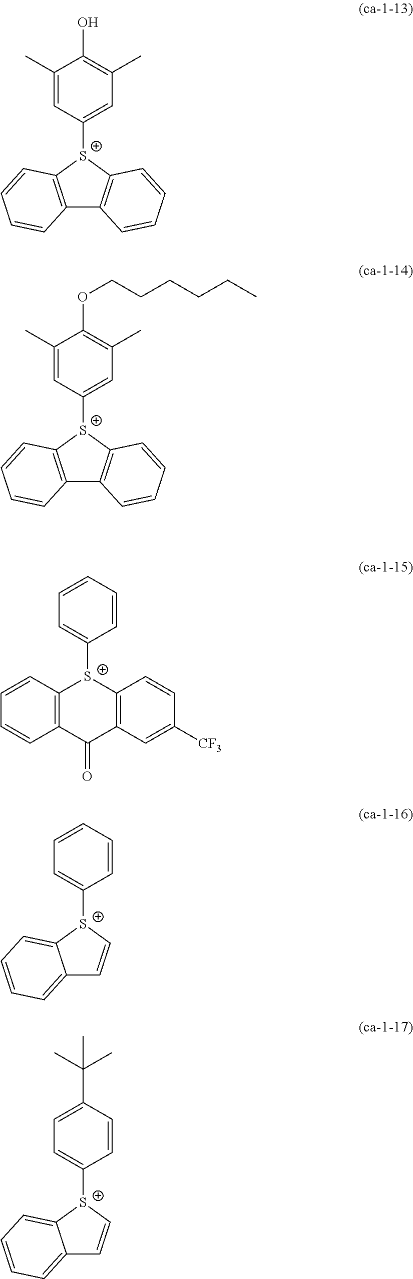 [SMILES: Cc1cc(-[s+]2c3ccccc3c3ccccc32)cc(C)c1O ; CCCCCCOc1c(C)cc(-[s+]2c3ccccc3c3ccccc32)cc1C ; O=c1c2ccccc2[s+](-c2ccccc2)c2ccc(C(F)(F)F)cc12 ; c1ccc(-[s+]2ccc3ccccc32)cc1 ; CC(C)(C)c1ccc(-[s+]2ccc3ccccc32)cc1]

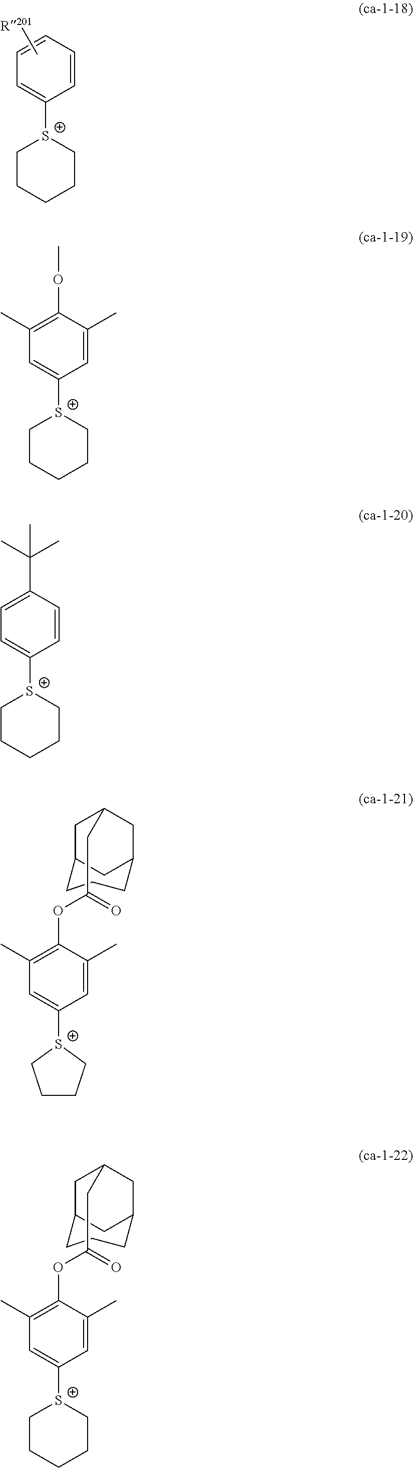

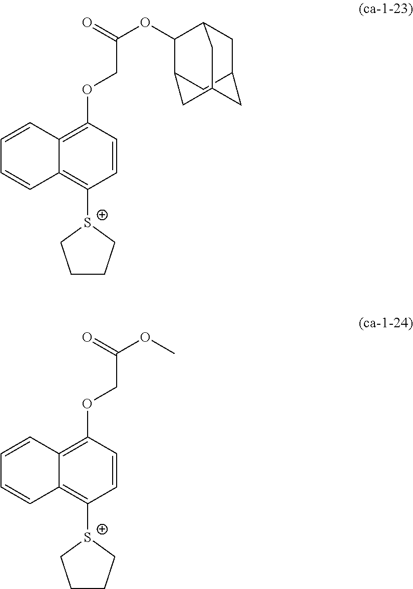 [SMILES: O=C(COc1ccc([S+]2CCCC2)c2ccccc12)OC1C2CC3CC(C2)CC1C3 ; COC(=O)COc1ccc([S+]2CCCC2)c2ccccc12]

[in the formulae, R″²⁰¹ represents a hydrogen atom or a substituent, and examples of the substituent include exemplary examples as the substituents which may be included in R^{20′} to R²⁰⁷ and R²¹⁰ to R²¹²]

Further, as the cation represented by Formula (ca-1), cations represented by Formulae (ca-1-25) to (ca-1-35) are also preferable.

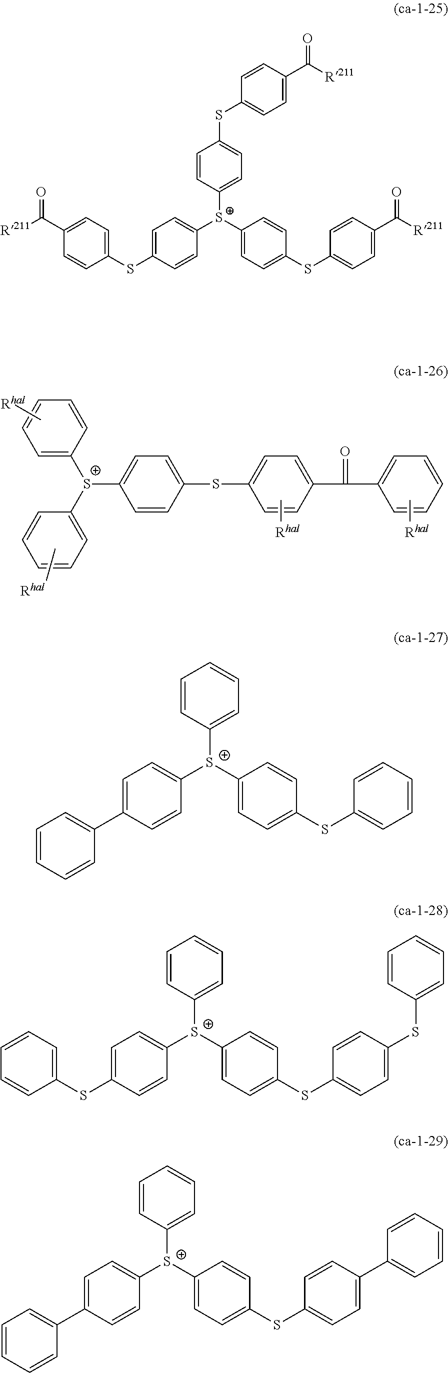

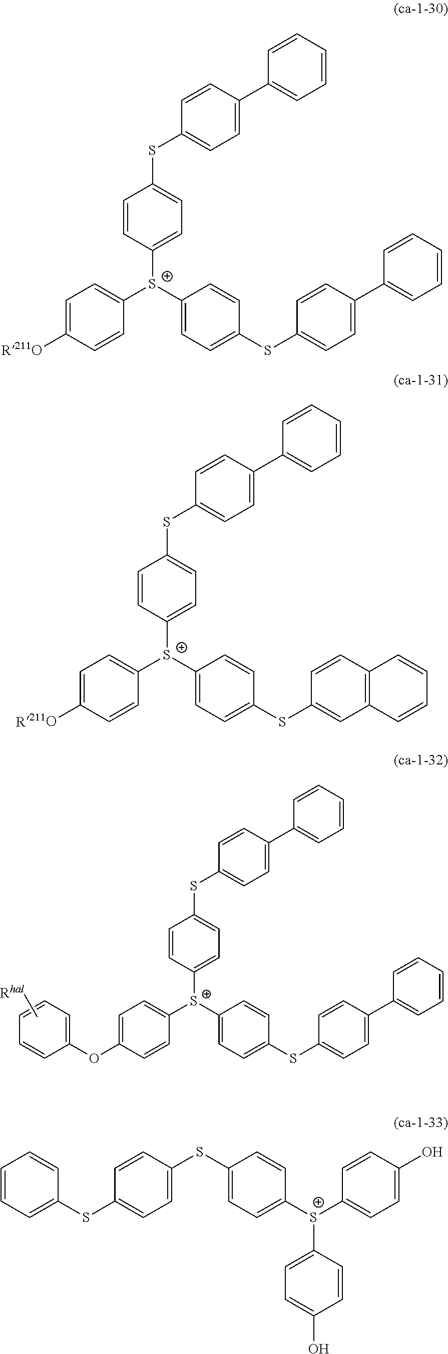

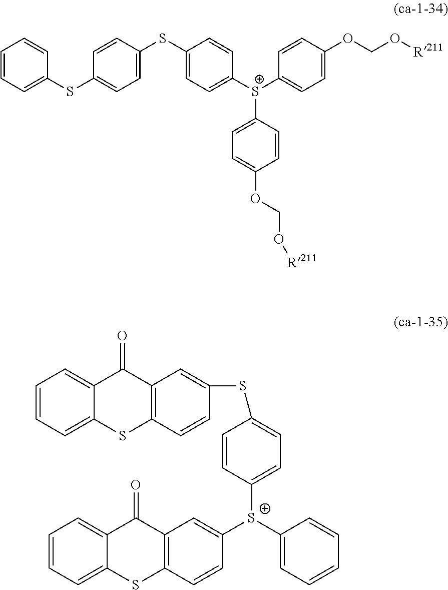

[in the formulae, R′²¹¹ represents an alkyl group, and R^{ba1} represents a hydrogen atom or a halogen atom]

Further, as the cation represented by Formula (ca-1), cations represented by Chemical Formulae (ca-1-36) to (ca-1-46) are also preferable.

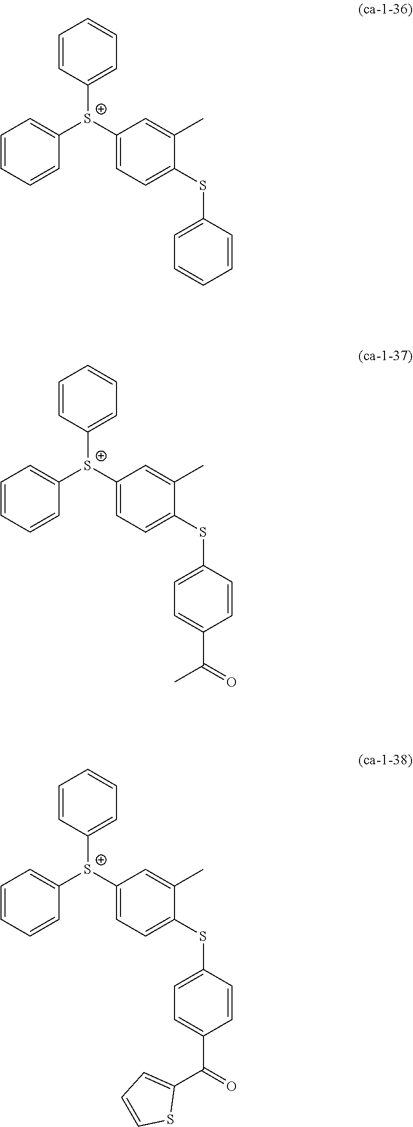 [SMILES: Cc1cc([S+](c2ccccc2)c2ccccc2)ccc1Sc1ccccc1 ; CC(=O)c1ccc(Sc2ccc([S+](c3ccccc3)c3ccccc3)cc2C)cc1 ; Cc1cc([S+](c2ccccc2)c2ccccc2)ccc1Sc1ccc(C(=O)c2cccs2)cc1]

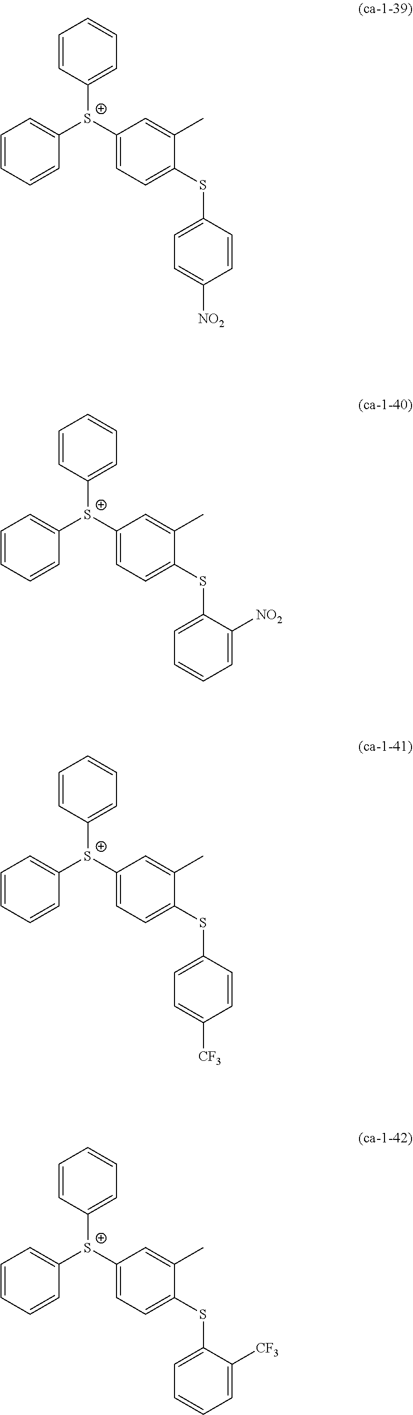 [SMILES: Cc1cc([S+](c2ccccc2)c2ccccc2)ccc1Sc1ccc([N+](=O)[O-])cc1 ; Cc1cc([S+](c2ccccc2)c2ccccc2)ccc1Sc1ccccc1[N+](=O)[O-] ; Cc1cc([S+](c2ccccc2)c2ccccc2)ccc1Sc1ccc(C(F)(F)F)cc1 ; Cc1cc([S+](c2ccccc2)c2ccccc2)ccc1Sc1ccccc1C(F)(F)F]

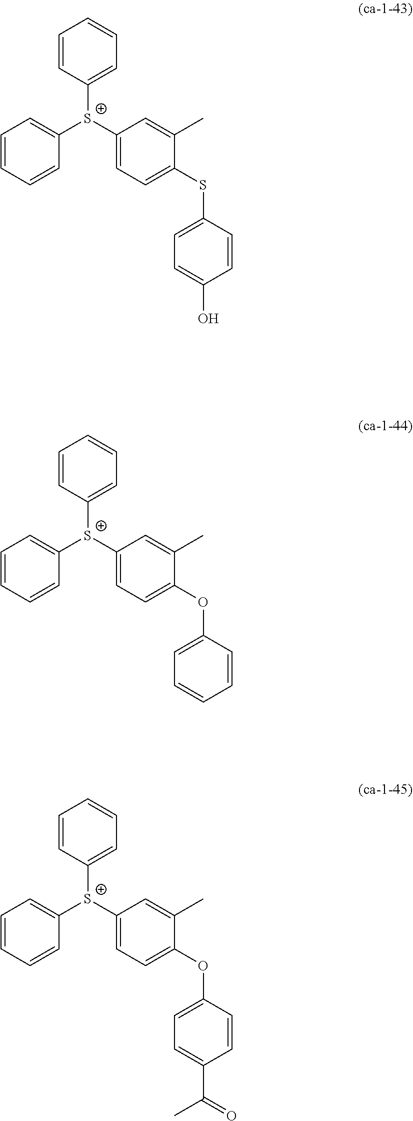 [SMILES: Cc1cc([S+](c2ccccc2)c2ccccc2)ccc1Sc1ccc(O)cc1 ; Cc1cc([S+](c2ccccc2)c2ccccc2)ccc1Oc1ccccc1 ; CC(=O)c1ccc(Oc2ccc([S+](c3ccccc3)c3ccccc3)cc2C)cc1]

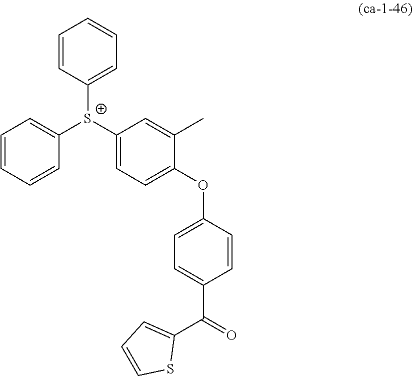 [SMILES: Cc1cc([S+](c2ccccc2)c2ccccc2)ccc1Oc1ccc(C(=O)c2cccs2)cc1]

Specific suitable examples of the cation represented by Formula (ca-2) include a diphenyliodonium cation and a bis(4-tert-butylphenyl)iodonium cation.

Specific suitable examples of the cation represented by Formula (ca-3) include cations represented by Formulae (ca-3-1) to (ca-3-6) shown below.

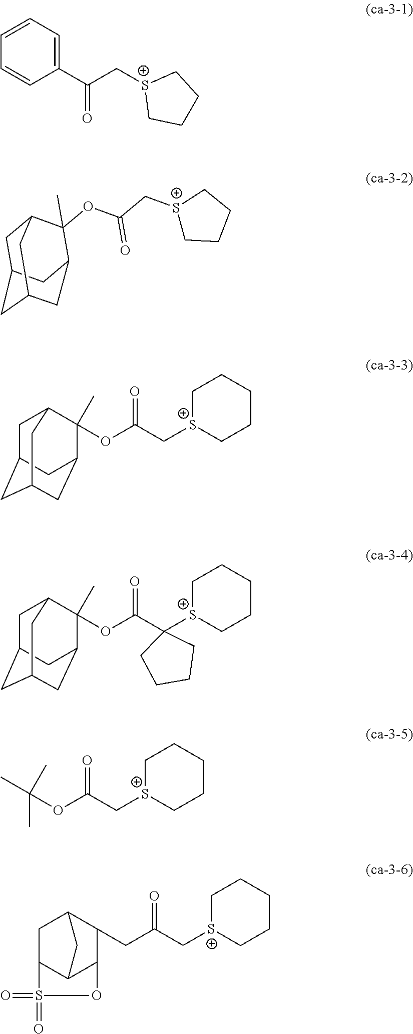 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(CC1C2CC3C1OS(=O)(=O)C3C2)C[S+]1CCCCC1]

Specific suitable examples of the cation represented by Formula (ca-4) include cations represented by Formulae (ca-4-1) and (ca-4-2) shown below.

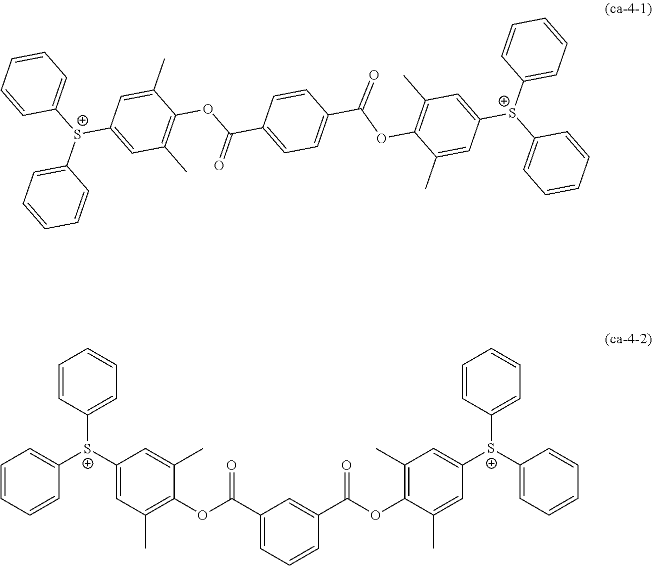 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

As the cation represented by Formula (ca-5), cations represented by Formulae (ca-5-1) to (ca-5-3) are preferable.

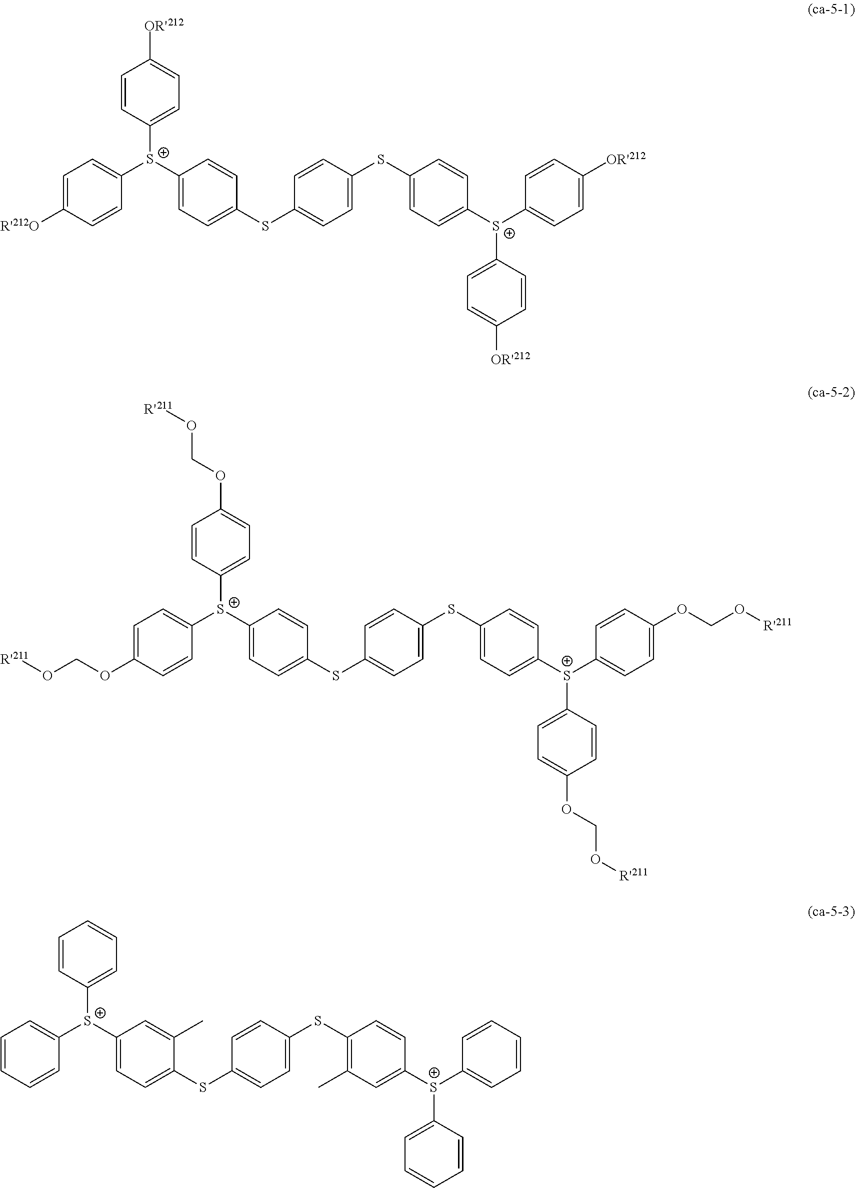

[in the formula, R′²¹² represents an alkyl group or a hydrogen atom, and R²¹¹ represents an alkyl group]

Among these, as the cation moiety [(Q^{q+})_{1/q}], a cation represented by Formula (ca-1) is preferable, cations represented by Formulae (ca-1-1) to (ca-1-46) are more preferable, and a cation represented by Formula (ca-1-29) is still more preferable.

<<Component (I2)>>

The component (I2) is a compound represented by Formula (I2).

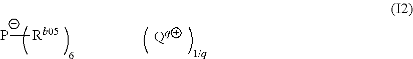

[in the formula, R^{b05} represents a fluorinated alkyl group which may have a substituent or a fluorine atom, a plurality of R^{b05}'s may be the same as or different from one another, q represents an integer of 1 or more, and Q^{q+}'s each independently represent a q-valent organic cation]

Anion Moiety

In Formula (I2), R^{b05} represents a fluorinated alkyl group which may have a substituent or a fluorine atom. A plurality of R^{b05}'s may be the same as or different from one another.

The fluorinated alkyl group in R^{b05} preferably has 1 to 10 carbon atoms, more preferably has 1 to 8 carbon atoms, and still more preferably has 1 to 5 carbon atoms. Specific examples thereof include a group in which some or all hydrogen atoms in an alkyl group having 1 to 5 carbon atoms are replaced with a fluorine atom.

Among the examples, R^{b05} represents preferably a fluorine atom or a fluorinated alkyl group having 1 to 5 carbon atoms, more preferably a fluorine atom or a perfluoroalkyl group having 1 to 5 carbon atoms, and still more preferably a fluorine atom, a trifluoromethyl group, or a pentafluoroethyl group.

It is preferable that the anion moiety of the compound represented by Formula (I2) is an anion moiety represented by Formula (b0-2a).

[(R^{bf05})_{nb}_{¹}PF_{(6-nb}_{¹}₎]^{⊖} (b0-2a)

[in the formula, R^{bf05} represents a fluorinated alkyl group which may have a substituent, and nb¹ represents an integer of 1 to 5]

In Formula (b0-2a), the fluorinated alkyl group which may have a substituent in R^{bf05} has the same definition as the fluorinated alkyl group which may have a substituent, which are exemplary examples as R^{b05}.

In Formula (b0-2a), nb¹ represents preferably an integer of 1 to 4, more preferably an integer of 2 to 4, and most preferably 3.

Cation Moiety

In Formula (I2), q represents an integer of 1 or more and Q^{q+}'s each independently represent a q-valent organic cation.

Examples of Q^{q+} include the same as those described in Formula (I1). Among these, a cation represented by Formula (ca-1) is preferable, cations represented by Formulae (ca-1-1) to (ca-1-46) are more preferable, and a cation represented by Formula (ca-1-35) is still more preferable.

<<Component (I3)>>

The component (I3) is a compound represented by Formula (I3-1) or Formula (I3-2).

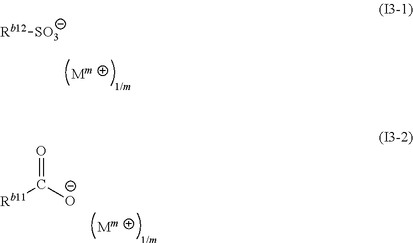

[in the formulae, R^{b11} and R^{b12} represent a cyclic group which may have a substituent other than a halogen atom, a chain-like alkyl group which may have a substituent other than a halogen atom, or a chain-like alkenyl group which may have a substituent other than a halogen atom, m represents an integer of 1 or more, and M^{m+}*'s each independently represent an m-valent organic cation]

{Component (I3-1)}

Anion Moiety

In Formula (I3-1), R^{b12} represents a cyclic group which may have a substituent other than a halogen atom, a chain-like alkyl group which may have a substituent other than a halogen atom, or a chain-like alkenyl group which may have a substituent other than a halogen atom, and examples thereof include those that do not have a substituent and those having a substituent other than a halogen atom, among the cyclic group, the chain-like alkyl group, and the chain-like alkenyl group in the description for R′²⁰¹ above.

It is preferable that R^{b12} represents a chain-like alkyl group which may have a substituent other than a halogen atom or an aliphatic cyclic group which may have a substituent other than a halogen atom.

The number of carbon atoms in the chain-like alkyl group is preferably 1 to 10 and more preferably 3 to 10. As the aliphatic cyclic group, a group (which may have a substituent other than a halogen atom) formed by removing one or more hydrogen atoms from adamantane, norbornane, isobornane, tricyclodecane, tetracyclododecane, or the like; or a group formed by removing one or more hydrogen atoms from camphor or the like is more preferable.

The hydrocarbon group as R^{b12} may have a substituent other than a halogen atom. Examples of the substituent include the same as the substituents other than a halogen atom, which may be included in the hydrocarbon group (such as an aromatic hydrocarbon group, an aliphatic cyclic group, or a chain-like alkyl group) in R^{b1} in Formula (I3-2).

The expression “may have a substituent other than a halogen atom” here excludes not only a case of having a substituent formed of only a halogen atom but also a case of having a substituent having even one halogen atom (for example, a case where the substituent is a fluorinated alkyl group).

Specific preferred examples of the anion moiety of the component (I3-1) are shown below.

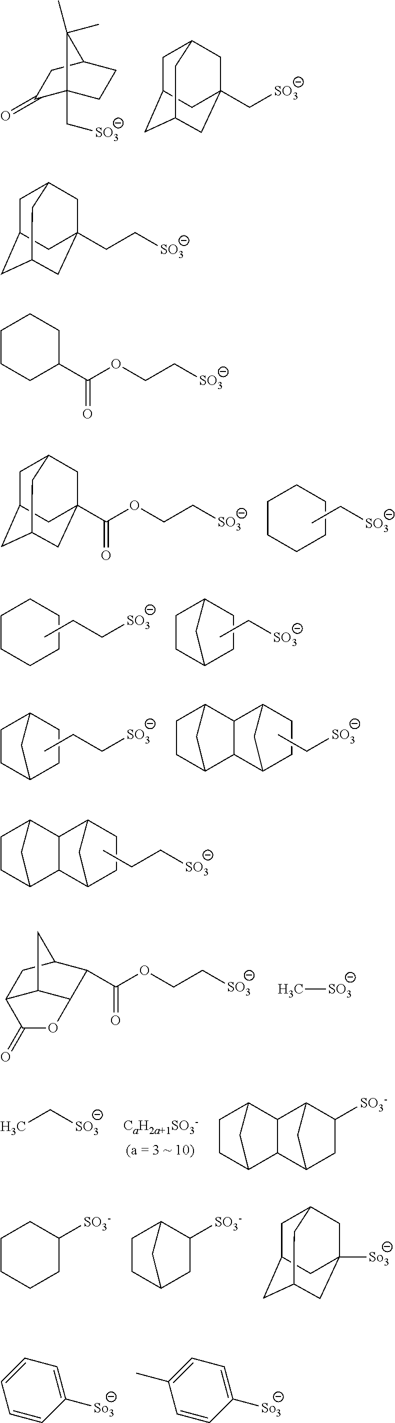

Cation Moiety

In Formula (I3-1), M^{m+} represents an m-valent organic cation.

Suitable examples of the organic cation as are the same as the cations represented by Formulae (ca-1) to (ca-5). Among these, a cation represented by the Formula (ca-1) is more preferable. In addition, a sulfonium cation in which at least one of R²⁰¹, R²⁰², and R²⁰³ in Formula (ca-1) represents an organic group (such as an aryl group, a heteroaryl group, an alkyl group, or an alkenyl group) which may have a substituent and has 16 or more carbon atoms is particularly preferable from the viewpoint of improving resolution and roughness characteristics.

Examples of the substituent which may be included in the organic group include, as described above, an alkyl group, a halogen atom, a halogenated alkyl group, a carbonyl group, a cyano group, an amino group, an oxo group (═O), an aryl group, and groups represented by Formulae (ca-r-1) to (ca-r-10).

The number of carbon atoms in the above-described organic group (such as an aryl group, a heteroaryl group, an alkyl group, or an alkenyl group) is preferably 16 to 25, more preferably 16 to 20, and particularly preferably 16 to 18. Suitable examples of the organic cation as M^{m+} include cations represented by Formulae (ca-1-25), (ca-1-26), (ca-1-28) to (ca-1-36), (ca-1-38), and (ca-1-46). Among these, a cation represented by Formula (ca-1-29) is particularly preferable.

{Component (I3-2)}

Anion Moiety

In Formula (I3-2), R^{b11} represents a cyclic group which may have a substituent other than a halogen atom, a chain-like alkyl group which may have a substituent other than a halogen atom, or a chain-like alkenyl group which may have a substituent other than a halogen atom, and examples thereof include those that do not have a substituent and those having a substituent other than a halogen atom, among the cyclic group, the chain-like alkyl group, and the chain-like alkenyl group in the description for R′²⁰¹ above.

Among these, it is preferable that R^{b11} represents an aromatic hydrocarbon group which may have a substituent other than a halogen atom, an aliphatic cyclic group which may have a substituent other than a halogen atom, and a chain-like alkyl group which may have a substituent other than a halogen atom. Examples of the substituents which may be included in these groups include a hydroxyl group, an oxo group, an alkyl group, an aryl group, a lactone-containing cyclic group, an ether bond, an ester bond, and a combination of these.

In a case where an ether bond or an ester bond is included as the substituent, the substituent may be bonded through an alkylene group, and linking groups represented by Formulae (y-a1-1) to (y-a1-7) are preferable as the substituent in this case.

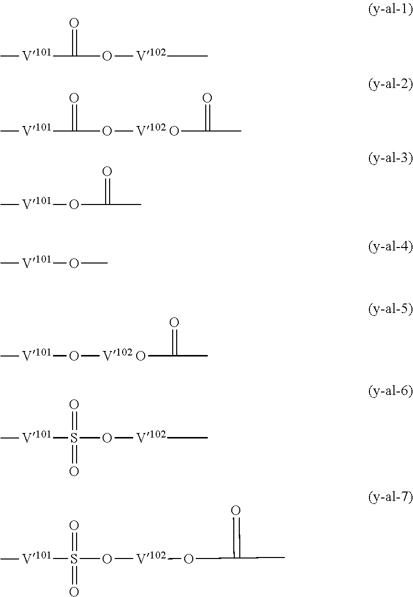

[in the formulae, V′¹⁰¹ represents a single bond or an alkylene group having 1 to 5 carbon atoms, and V′¹⁰² represents a divalent saturated hydrocarbon group having 1 to 30 carbon atoms]

As the divalent saturated hydrocarbon group in V′¹⁰², an alkylene group having 1 to 30 carbon atoms is preferable, an alkylene group having 1 to 10 carbon atoms is more preferable, and an alkylene group having 1 to 5 carbon atoms is still more preferable.

The alkylene group in V′¹⁰¹ and V′¹⁰² may be a linear alkylene group or a branched alkylene group, and a linear alkylene group is preferable.

Specific examples of the alkylene group in V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

Further, some methylene groups in the alkylene group in V′¹⁰¹ or V′¹⁰² may be replaced with a divalent aliphatic cyclic group having 5 to 10 carbon atoms. As the aliphatic cyclic group, a divalent group formed by further removing one hydrogen atom from a cyclic aliphatic hydrocarbon group as R′²⁰¹ (a monocyclic alicyclic hydrocarbon group or a polycyclic alicyclic hydrocarbon group) is preferable, and a cyclohexylene group, a 1,5-adamantylene group, or a 2,6-adamantylene group is more preferable.

As the aromatic hydrocarbon group, a phenyl group or a naphthyl group is more preferable.

As the aliphatic cyclic group, a group formed by removing one or more hydrogen atoms from a polycycloalkane such as adamantane, norbornane, isobornane, tricyclodecane, or tetracyclododecane is more preferable.

The number of carbon atoms in the above-described chain-like alkyl group is preferably 1 to 10, and specific examples thereof include a linear alkyl group such as a methyl group, an ethyl group, a propyl group, a butyl group, a pentyl group, a hexyl group, a heptyl group, an octyl group, a nonyl group, or a decyl group; and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

It is preferable that R^{b11} represents a cyclic group which may have a substituent other than a halogen atom.

Specific preferred examples of the anion moiety of the component (I3-2) are shown below.

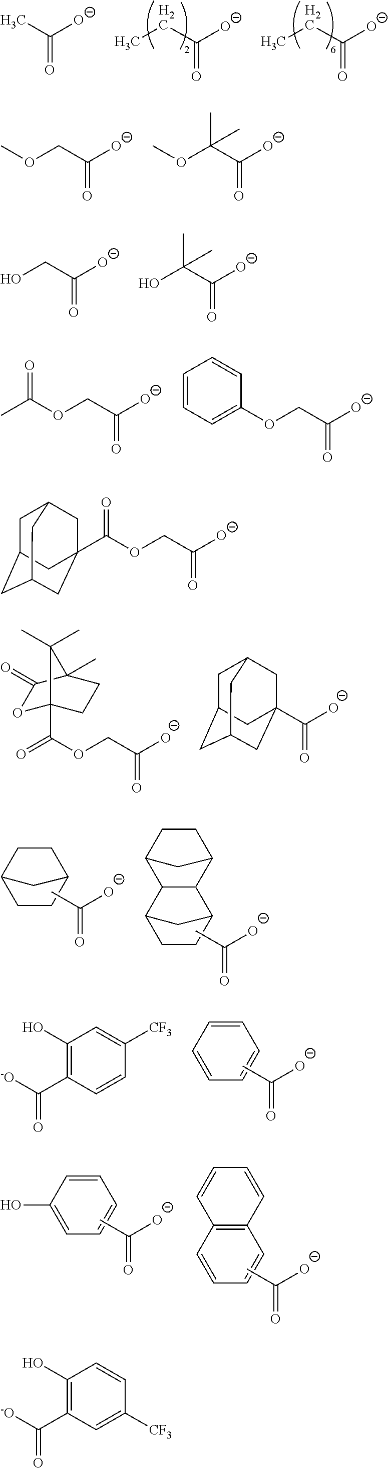

Cation Moiety

In Formula (I3-2), M^{m+} represents an m-valent organic cation and has the same definition as that for M^{m+} in Formula (I3-1).

From the viewpoints of high elasticity of a resin film and ease of forming a fine structure without residues, it is preferable that the component (I) is a cationic polymerization initiator which generates an acid having a pKa (acid dissociation constant) of −5 or less upon exposure. It is possible to obtain high sensitivity upon exposure by using a cationic polymerization initiator that generates an acid having a pKa of more preferably −6 or less and still more preferably −8 or less. The lower limit value of the pKa of the acid generated from the component (I) is preferably −15 or more. The sensitivity is likely to be increased by using a cationic polymerization initiator that generates an acid having a pKa in the above-described suitable range.

Here, “pKa (acid dissociation constant)” is typically used as an index showing the acid strength of a target substance. Further, the pKa in the present specification is a value obtained under a temperature condition of 25° C. Further, the pKa value can be acquired by performing measurement according to a known technique. In addition, calculated values obtained by using a known software such as “ACD/Labs” (trade name, manufactured by Advanced Chemistry Development Inc.) can be used.

Specific examples of the suitable component (I) are shown below.

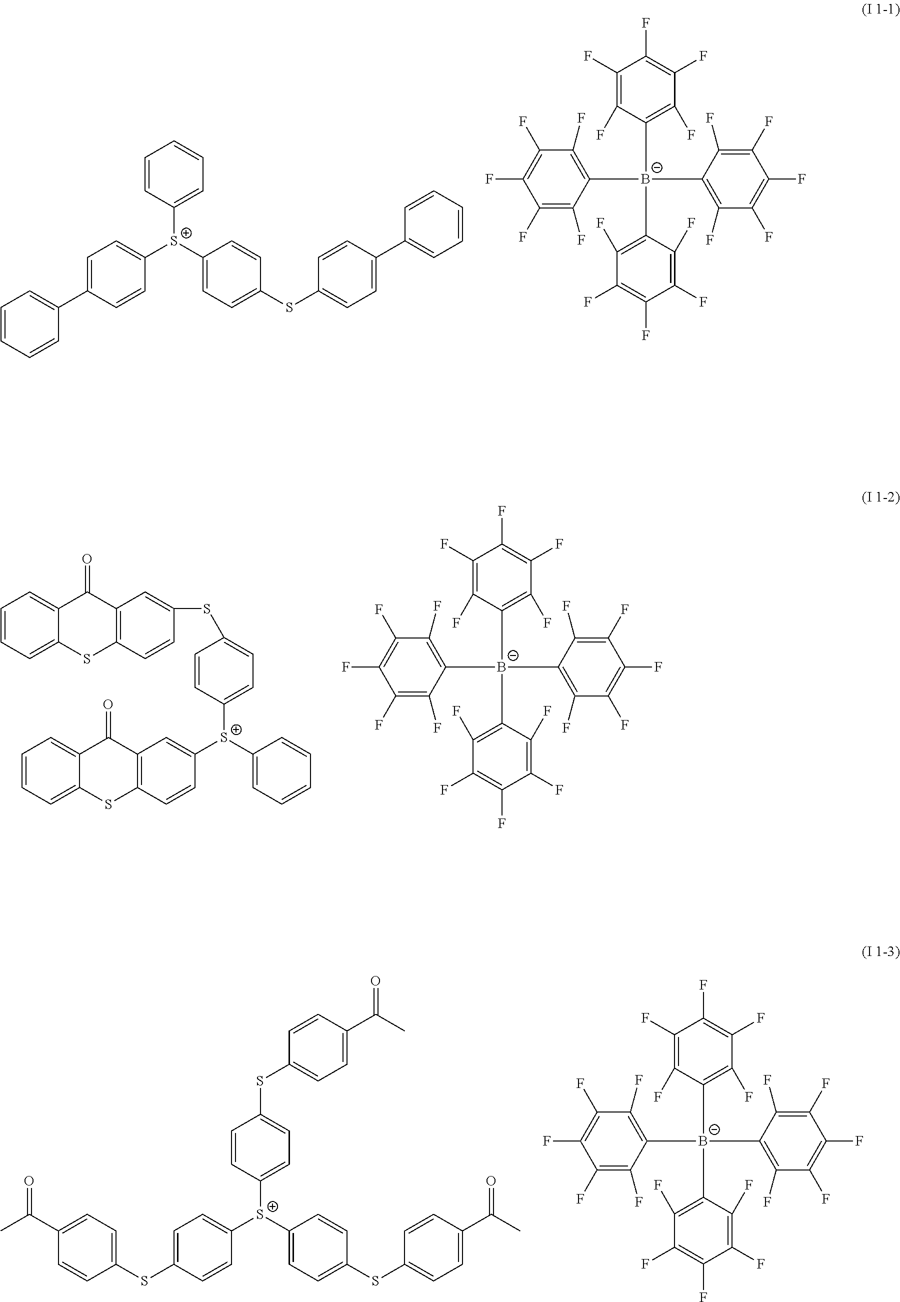

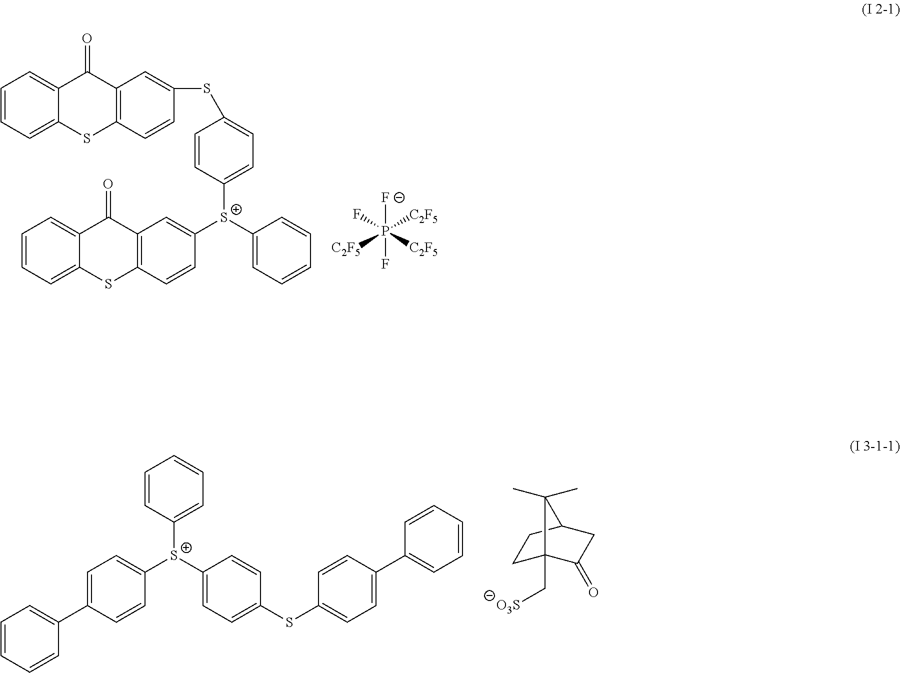

The component (I) may be used alone or in combination of two or more kinds thereof.

It is preferable that the component (I) includes two or more components selected from the group consisting of the component (I1), the component (I2), and the component (I3), it is more preferable to include two or more components selected from the group consisting of the component (I1) and the component (I2), and it is still more preferable to include a combination of the component (I1) and the component (I2).

The content of the component (I) is preferably 2.0 to 6.0 parts by mass, more preferably 2.5 to 5.5 parts by mass, and still more preferably 3.0 to 5.0 parts by mass with respect to 100 parts by mass of the component (A).

In a case where the content of the component (I) is greater than or equal to the lower limit value of the above-described preferred range, sufficient sensitivity is obtained, and lithography characteristics of the pattern are further improved. In addition, the hardness of the cured film is further increased. On the other hand, in a case of being lower than or equal to the upper limit value of the above-described preferred range, the sensitivity is appropriately controlled, and a pattern having a favorable shape is easily obtained.

In addition, the content of the component (I) is preferably 1.5 to 5 parts by mass, more preferably 1.6 to 4 parts by mass, and still more preferably 1.7 to 3 parts by mass with respect to 100 parts by mass of the total amount of the component (A) and the component (M).

In a case where the content of the component (I) is within the above-described preferred range, the hardness of the cured film is further increased, a high-resolution pattern is easily formed with a favorable shape.

In the photosensitive composition according to the present embodiment, the content of the component (A) with respect to a total amount of the component (A), the component (I), and the component (M) described above is preferably 35% by mass or more and less than 70% by mass, more preferably 40% to 60% by mass, and still more preferably 45% to 55% by mass.

In a case where the content of the component (A) is within the above-described preferred range, the hardness of the cured film is further increased, and the film characteristics (rolling and laminating properties) is further improved in a case where the photosensitive resist film is formed.

<Other Components>

The photosensitive composition according to the present embodiment may contain other components as necessary, in addition to the component (A), the component (M), and the component (I) described above.

In the photosensitive composition according to the embodiment, it is possible to optionally add and contain miscible additives such as an additive resin for improving film performance, a dissolution inhibitor, a basic compound, a plasticizer, a stabilizer, a colorant, and a halation-preventing agent.

<<Silane Coupling Agent>>

In addition, in order to improve adhesiveness with the support, the photosensitive composition according to the embodiment may further contain an adhesive aid. As the adhesive aid, a silane coupling agent is preferable.

Examples of the silane coupling agent include silane coupling agents having reactive substituents such as a carboxy group, a methacryloyl group, an isocyanate group, and an epoxy group. Specific examples thereof include trimethoxysilylbenzoic acid, γ-methacryloxypropyltrimethoxysilane, vinyltriacetoxysilane, vinyltrimethoxysilane, γ-glycidoxypropyltrimethoxysilane, and β-(3,4-epoxycyclohexyl)ethyltrimethoxysilane.

The silane coupling agent may be used alone or in combination of two or more kinds thereof.

In a case where the silane coupling agent is added to the photosensitive composition according to the embodiment, the content of the silane coupling agent is preferably 2.5 to 20 parts by mass, more preferably 3 to 15 parts by mass, and still more preferably 3 to 10 parts by mass with respect to 100 parts by mass of the component (A).

In a case where the content of the silane coupling agent is within the above-described preferred range, the hardness of the cured film is further increased. In addition, the adhesiveness between the cured film and the support is further strengthened.

<<Sensitizer Component>>

The photosensitive composition according to the embodiment may further contain a sensitizer component.

The sensitizer component is not particularly limited as long as it can absorb energy from exposure and transfer the energy to other substances.

As a specific example of the sensitizer component, benzophenone-based photosensitizers such as benzophenone and p,p′-tetramethyldiaminobenzophenone, carbazole-based photosensitizers, acetophen-based photosensitizers, naphthalene-based photosensitizers such as 1,5-dihydroxynaphthalene, phenol-based photosensitizers, anthracene-based photosensitizers such as 9-ethoxyanthracene, and known photosensitizers such as diacetyl, eosin, rose bengal, pyrene, phenothiazine, and anthrone can be used.

The sensitizer component may be used alone or in combination of two or more kinds thereof.

In a case where the sensitizer component is added to the photosensitive composition according to the embodiment, the content of the sensitizer component is preferably 0.1 to 15 parts by mass, more preferably 0.3 to 10 parts by mass, and still more preferably 0.5 to 5 parts by mass with respect to 100 parts by mass of the component (A).

In a case where the content of the sensitizer component is within the above-described preferred range, the sensitivity and the resolvability are further enhanced.

<<Solvent>>

The photosensitive composition according to the embodiment can be produced by dissolving or dispersing a photosensitive material in a solvent (hereinafter, may be referred to as a “component (S)”).

Examples of the component (S) include lactones such as γ-butyrolactone; ketones such as acetone, methyl ethyl ketone (MEK), cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monoethylether, monopropylether, or monobutylether or monophenylether of any of the polyhydric alcohols or the compounds having an ester bond [among these, methoxybutyl acetate, propylene glycol monomethyl ether acetate (PGMEA), or propylene glycol monomethyl ether (PGME) is preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and dimethylsulfoxide (DMSO).

The component (S) may be used alone or in the form of a mixed solvent of two or more kinds thereof.

The amount of the component (S) to be used is not particularly limited and is appropriately set so as to have a concentration suitable for application to a substrate or the like depending on the thickness of a coating film.

The content of the component (S) in the photosensitive composition is preferably 1% to 25% by mass and more preferably 5% to 20% by mass with respect to the total amount (100% by mass) of the photosensitive composition.

[Martens Hardness of Photosensitive Resin Film]

In the negative-working photosensitive resin composition according to the present embodiment, in a case of applying the above-described negative-working photosensitive resin composition onto a silicon wafer and performing a bake treatment at 90° C. for 5 minutes to obtain a photosensitive resin film having a film thickness of 20 μm, the film has a Martens hardness of less than 235 [N/mm²], preferably 15 to 200 [N/mm²] and more preferably 40 to 160 [N/mm²].

In a case where the Martens hardness of the photosensitive resin film is lower than or equal to the upper limit value of the above-described range, the photosensitive resin film has appropriate flexibility in a case of being formed into a photosensitive resist film, and film characteristics (rolling and laminating properties) thereof are excellent. On the other hand, in a case of being greater than or equal to the lower limit value of the above-described preferred range, the hardness of the cured film in a case of being cured is further increased.

The Martens hardness of the photosensitive resin film is measured by a nanoindentation method shown below.
Evaluation method: micro hardness test in conformity with IS014577 with a FISCHERSCOPE HM2000 measuring device (manufactured by FISCHER INSTRUMENTS K.K.)
Measurement conditions: maximum test load: 30 mN, load application time: 20 seconds, creep time: 5 seconds, temperature: 25° C.

The above-described Martens hardness of photosensitive resin film can be controlled to be less than 235 [N/mm²] by selecting the type of the component to be blended in the negative-working photosensitive resin composition or appropriately adjusting the blending ratio thereof.

It is preferable to select the type of the epoxy group-containing resin (A) is selected, or appropriately adjust the blending ratio thereof. Particular examples thereof include an aspect in which a combination of the component (A1) and the component (m) is adopted as the component (A) and an aspect in which a combination of the component (m1) and the component (m2) is adopted as the component (m).

[Tensile Elastic Modulus (E*) of Cured Film]

In the present embodiment, in a case where a tensile elastic modulus (E*) of a cured film, which is obtained by exposing, to i-rays at an irradiation amount of 200 mJ/cm², a photosensitive resin film that is formed by performing a bake treatment at 90° C. for 5 minutes to the above-described negative-working photosensitive resin composition and has a film thickness of 20 μm, performing a bake treatment after the exposure at 90° C. for 5 minutes, and then performing a bake treatment at 200° C. for 1 hour to cure the photosensitive resin film, is 2.1 [GPa] or more, preferably 2.3 to 4.0 [GPa] and more preferably 2.5 to 3.5 [GPa].

In a case where the tensile elastic modulus (E*) of the cured film is greater than or equal to the lower limit value of the above-described range, the cured film has sufficient hardness, and in a case where a hollow structure is formed, a space is sufficiently maintained even in a case where a high pressure is applied. On the other hand, in a case of being lower than or equal to the upper limit value of the above-described preferred range, generation of cracks in the cured film is likely to be suppressed.

The tensile elastic modulus (E*) of the cured film is a value measured at a temperature of 175° C. in a case where a viscoelasticity of the cured film is measured at a frequency of 1.0 Hz.

The above-described tensile elastic modulus (E*) of cured film can be controlled to be 2.1 [GPa] or more by selecting the type of the component to be blended in the negative-working photosensitive resin composition or appropriately adjusting the blending ratio thereof.

It is preferable to increase the content of the metal oxide (M), select the type of the epoxy group-containing resin (A) is selected, or appropriately adjust the blending ratio thereof. Particular examples thereof include an aspect in which the content of the component (M) is more than 30 parts by mass with respect to 100 parts by mass of the component (A).

(Photosensitive Resist Film)

The photosensitive resist film according to the present embodiment is a photosensitive resist film obtained by laminating a negative-working photosensitive resin film containing an epoxy group-containing resin (A), a metal oxide (M), and a cationic polymerization initiator (T) on a base film.

In addition, in the photosensitive resist film according to the present embodiment, in a case where the negative-working photosensitive resin film is laminated on a silicon wafer to a film thickness of 20 μm, the negative-working photosensitive resin film has a Martens hardness of less than 235 [N/mm²], and in a case where a viscoelasticity of a cured film, which is obtained by exposing the photosensitive resin film to i-rays at an irradiation amount of 200 mJ/cm², performing a bake treatment after the exposure at 90° C. for 5 minutes, and then performing a bake treatment at 200° C. for 1 hour to cure the photosensitive resin film, is measured at a frequency of 1.0 Hz, a tensile elastic modulus (E*) of the cured film at a temperature of 175° C. is 2.1 [GPa] or more.

Here, the photosensitive resin film in the photosensitive resist film according to the present embodiment is typically composed of a B-stage (semi-cured) resin material. The above-described Martens hardness is a value measured in a case where the photosensitive resin film is laminated on the silicon wafer with a film thickness of 20 μm. Laminating is performed under the conditions of 90° C., 0.3 MPa, and 0.5 μm/min.

In a case where the photosensitive resin film in the photosensitive resist film according to the present embodiment has a film thickness of less than 20 μm, by laminating a plurality of photosensitive resin films on the silicon wafer (grinding after the laminating as necessary), the film thickness thereof may be adjusted to be 20 μm and the Martens hardness may be measured. In addition, in a case where the photosensitive resin film in the photosensitive resist film according to the present embodiment has a film thickness of more than 20 μm, by laminating a resin film on the silicon wafer and then grinding the resin film, the film thickness thereof may be adjusted to be 20 μm and the Martens hardness may be measured. As the measurement conditions of the Martens hardness of a sample in which the film thickness has been adjusted, the nanoindentation method described above may be adopted.

In a case where a photosensitive resin film is formed of such a photosensitive resist film and selective exposure is performed on the photosensitive resin film, since a cation moiety of the component (I) is decomposed to generate an acid in an exposed portion of the photosensitive resin film, and an epoxy group in the component (A) is subjected to ring-opening polymerization due to an action of the acid so that the solubility of the component (A) in a developing solution containing an organic solvent is decreased while the solubility of the component (A) in the developing solution containing an organic solvent is not changed in an unexposed portion of the photosensitive resin film. Therefore, a difference in solubility in the developing solution containing an organic solvent occurs between the exposed portion of the photosensitive resin film and the unexposed portion of the photosensitive resin film. That is, the photosensitive resin film is negative-working. Accordingly, in a case where the photosensitive resin film is developed with the developing solution containing an organic solvent, the unexposed portion is dissolved and removed so that a negative-working pattern is formed.

The photosensitive resist film according to the embodiment can be produced by coating a base film with the negative-working photosensitive resin composition according to the embodiment described above, and drying the composition to form a photosensitive resin film.

The base film may be coated with the negative-working photosensitive resin composition according to an appropriate method using an applicator, a blade coater, a lip coater, a comma coater, a film coater, or the like.

The thickness of the photosensitive resin film is preferably 100 μm or less and more preferably 5 to 50 μm.

<Base Film>

In the photosensitive resist film according to the embodiment, as the base film, known films such as a thermoplastic resin film are used. Examples of the thermoplastic resin include polyesters such as polyethylene terephthalate. The thickness of the base film is preferably 2 to 150 μm.

<Photosensitive Resin Film>

The negative-working photosensitive resin film in the photosensitive resist film according to the embodiment contains an epoxy group-containing resin (A), a metal oxide (M), and a cationic polymerization initiator (I). Hereinafter, each of these components is also referred to as a component (A), a component (M), and a component (I), same as the case of the above-described negative-working photosensitive resin composition.

Each of the descriptions of the component (A), the component (M), and the component (I) contained in the negative-working photosensitive resin film is the same as the descriptions for the component (A), the component (M), and the component (I) contained in the negative-working photosensitive resin composition described above.

The negative-working photosensitive resin film may contain other components as necessary, in addition to the component (A), component (M), and component (I) described above. Examples of the other components include a silane coupling agent, a sensitizer component, a solvent, and miscible additives (such as an additive resin for improving film performance, a dissolution inhibitor, a basic compound, a plasticizer, a stabilizer, a colorant, and a halation-preventing agent).

[Martens Hardness of Photosensitive Resin Film]

In the photosensitive resist film according to the present embodiment, in a case where the negative-working photosensitive resin film is laminated on a silicon wafer to a film thickness of 20 μm, the negative-working photosensitive resin film has a Martens hardness of less than 235 [N/mm²], preferably 15 to 200 [N/mm²] and more preferably 40 to 160 [N/mm²].

In a case where the Martens hardness of the photosensitive resin film is lower than or equal to the upper limit value of the above-described range, the photosensitive resin film has appropriate flexibility in a case of being formed into a photosensitive resist film, and film characteristics (rolling and laminating properties) thereof are excellent. On the other hand, in a case of being greater than or equal to the lower limit value of the above-described preferred range, the hardness of the cured film in a case of being cured is further increased.

The Martens hardness of the photosensitive resin film is measured by laminating the photosensitive resin film on a silicon wafer to a film thickness of 20 μm as described above, and using a nanoindentation method shown below.
Evaluation method: micro hardness test in conformity with ISO14577 with a FISCHERSCOPE HM2000 measuring device (manufactured by FISCHER INSTRUMENTS K.K.)
Measurement conditions: maximum test load: 30 mN, load application time: 20 seconds, creep time: 5 seconds, temperature: 25° C.

[Tensile Elastic Modulus (E*) of Cured Film]

In the photosensitive resist film according to the present embodiment, in a case where a tensile elastic modulus (E*) of a cured film, which is obtained by exposing, to i-rays at an irradiation amount of 200 mJ/cm², a photosensitive resin film having a film thickness of 20 am, performing a bake treatment after the exposure at 90° C. for 5 minutes, and then performing a bake treatment at 200° C. for 1 hour to cure the photosensitive resin film, is 2.1 [GPa] or more, preferably 2.3 to 4.0 [GPa] and more preferably 2.5 to 3.5 [GPa].

In a case where the tensile elastic modulus (E*) of the cured film is greater than or equal to the lower limit value of the above-described range, the cured film has sufficient hardness, and in a case where a hollow structure is formed, a space is sufficiently maintained even in a case where a high pressure is applied. On the other hand, in a case of being lower than or equal to the upper limit value of the above-described preferred range, generation of cracks in the cured film is likely to be suppressed.

The tensile elastic modulus (E*) of the cured film is a value measured at a temperature of 175° C. in a case where a viscoelasticity of the cured film is measured at a frequency of 1.0 Hz.

As described above, in the negative-working photosensitive resin composition or photosensitive resist film according to the present embodiment (photosensitive material according to the present embodiment, the Martens hardness of a photosensitive resin film (so-called B-stage (semi-cured) resin film) having a film thickness of 20 μm is less than 235 [N/mm²] and the tensile elastic modulus (E*) of a cured film thereof (completely cured) is 2.1 [GPa] or more. From such characteristics, according to the photosensitive material according to the present embodiment, a cured film having a higher hardness can be obtained. As a result, the hollow structure can be maintained even with high pressure applied during molding. In addition, in the photosensitive material according to the present embodiment, the hardness of the cured film is increased, while decrease in tackiness of the photosensitive resin film is suppressed, so that the photosensitive resin film is easy to roll and has excellent laminating properties for a substrate or the like.

Furthermore, according to the photosensitive material according to the present embodiment, a high-resolution pattern having sufficient sensitivity, reduced residues, and favorable shape can also be formed.

The photosensitive resist film according to one aspect of the present invention is not limited to the above-described embodiment, and for example, the photosensitive resist film may be a photosensitive resist film composed of a laminate in which the photosensitive resin film and a cover film are laminated on the base film in this order.

As the cover film, known films such as a polyethylene film and a polypropylene film are used. As the cover film, a film of which adhesive force to the photosensitive resin film is smaller than that of the base film is preferable. The thickness of the cover film is preferably 2 to 150 μm, more preferably 2 to 100 μm, and still more preferably 5 to 50 μm.

The base film and the cover film may be formed of the same film material or may be different films.

In use, for example, a pattern can be formed on a support by laminating a laminate of photosensitive resin film/base film on the support while peeling off the cover film, peeling off the base film, and then performing exposure and development.

(Pattern Formation Method)

A pattern formation method according to the present embodiment includes a step of forming a photosensitive resin film on a support (hereinafter, referred to as a “film formation step”) using the negative-working photosensitive resin composition or the photosensitive resist film according to the embodiment described above; a step of exposing the photosensitive resin film (hereinafter, referred to as an “exposure step”); and a step of developing the exposed photosensitive resin film with a developing solution containing an organic solvent to form a negative-working pattern (hereinafter, referred to as a “development step”).

For example, the pattern formation method according to the present embodiment can be performed in the following manner.

[Film Formation Step]

First, a photosensitive resin film is formed by coating a support with the negative-working photosensitive resin composition according to the embodiment using known methods such as a spin coating method, a roll coating method, or a screen printing method and by performing a bake (post apply bake (PAB)) treatment under a temperature condition of, for example, 50° C. to 150° C. for 2 to 60 minutes.

In the film formation step, a photosensitive resin film may be formed on a support by attaching the photosensitive resist film onto the support. During the attachment, the support or the film may be heated or pressed (laminated) as necessary.

The support is not particularly limited and a known support in the related art can be used. Examples of the support include substrates for electronic components, and such substrates having a predetermined wiring pattern formed thereon. More specific examples thereof include a substrate made of metal such as silicon wafer, copper, chromium, iron, or aluminum; a glass substrate; and a resin film such as polyethylene terephthalate, polyethylene naphthalate, polypropylene, or polyethylene. As the materials for the wiring pattern, copper, aluminum, nickel, and gold can be used.

Further, as the support, any one of the above-described substrates provided with an inorganic and/or organic film may be used. Examples of the inorganic film include an inorganic bottom anti-reflective coating (inorganic BARC). Examples of the organic film include organic films such as an organic bottom anti-reflective coating (organic BARC) and a lower layer organic film according to a multilayer resist method.

The film thickness of the photosensitive resin film to be formed using the negative-working photosensitive resin composition or the photosensitive resist film is not particularly limited, but is preferably approximately 10 to 100 μm. Even in a case where a thick film is formed using the negative-working photosensitive resin composition according to the embodiment, favorable characteristics are obtained.

[Exposure Step]

Next, the formed photosensitive resin film is exposed through a mask having a predetermined pattern (mask pattern) formed thereon using a known exposure device or selectively exposed through drawing or the like by performing direct irradiation with electron beams without using a mask pattern therebetween. In addition, a bake (post exposure bake (PEB)) treatment is performed as necessary under a temperature condition of 80° C. to 150° C. for 40 to 600 seconds, preferably 60 to 300 seconds.

The wavelength used in the exposure is not particularly limited, and the exposure is performed by selectively radiating (exposing) radiation, for example, ultraviolet rays having a wavelength of 300 to 500 nm, i-rays (wavelength of 365 nm), or visible light rays. As these radiation sources, a low pressure mercury lamp, a high pressure mercury lamp, an ultra-high pressure mercury lamp, a metal halide lamp, and an argon gas laser can be used.

Here, the radiation indicates ultraviolet rays, visible light rays, far ultraviolet rays, X rays, electron beams, or the like. The radiation amount varies depending on the type of each component in the composition, the blending amount thereof, the film thickness of the coating film, and the like. For example, in a case where an ultra-high pressure mercury lamp is used, the radiation amount thereof is 100 to 2000 mJ/cm².

The photosensitive resin film may be exposed through typical exposure (dry exposure) performed in air or an inert gas such as nitrogen or through liquid immersion exposure (liquid immersion lithography).

The photosensitive resin film after the exposure step is highly transparent, and the haze value in a case of irradiation with i-rays (wavelength of 365 nm) is preferably 3% or less and more preferably 1.0% to 2.7%.

As described above, the photosensitive resin film formed using the negative-working photosensitive resin composition or the photosensitive resist film according to the embodiment is highly transparent. Therefore, the light transmittance is increased during the exposure in pattern formation so that a negative-working pattern with favorable lithography characteristics is likely to be obtained.

The haze value of the photosensitive resin film after the exposure step is measured using a method in conformity with JIS K 7136 (2000).

[Development Step]

Next, the above-described exposed photosensitive resin film is developed with a developing solution (organic developing solution) containing an organic solvent. After the development, it is preferable that a rinse treatment is performed. As necessary, a bake treatment (post bake) may be performed.

By performing the above-described film formation step, exposure step, and development step, a pattern can be formed.

As the organic solvent contained in the organic developing solution, a solvent which is capable of dissolving the component (A) (component (A) before the exposure) may be used and can be appropriately selected from known organic solvents. Specific examples of the organic solvent include polar solvents such as ketone solvents, ester solvents, alcohol solvents, nitrile solvents, amide solvents, and ether solvents; and hydrocarbon solvents.

Examples of the ketone solvents include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylenecarbonate, γ-butyrolactone and methyl amyl ketone (2-heptanone). Among these examples, as the ketone solvents, methyl amyl ketone (2-heptanone) is preferable.

Examples of the ester solvents include methyl acetate, butyl acetate, ethyl acetate, isopropyl acetate, amyl acetate, isoamyl acetate, ethyl methoxyacetate, ethyl ethoxyacetate, propylene glycol monomethyl ether acetate (PGMEA), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these examples, as the ester solvents, butyl acetate or PGMEA is preferable.

Examples of the nitrile solvents include acetonitrile, propionitrile, valeronitrile, and butyronitrile.

Known additives can be blended with the organic developing solution as necessary. Examples of the additive include a surfactant. The surfactant is not particularly limited, and for example, an ionic or non-ionic fluorine-based and/or silicon-based surfactant can be used.

As the surfactant, a non-ionic surfactant is preferable, and a non-ionic fluorine-based surfactant or a non-ionic silicon-based surfactant is more preferable.

In a case where a surfactant is blended, the blending amount thereof is typically 0.001% to 5% by mass, preferably 0.005% to 2% by mass, and more preferably 0.01% to 0.5% by mass with respect to the total amount of the organic developing solution.

The development can be performed by a known developing method. Examples thereof include a method of immersing a support in a developing solution for a predetermined time (a dip method), a method of stacking up a developing solution on the surface of a support using the surface tension and maintaining the state for a predetermined time (a puddle method), a method of spraying a developing solution to the surface of a support (a spray method), and a method of continuously ejecting a developing solution from a developing solution ejecting nozzle onto a support rotating at a constant speed while scanning the developing solution ejecting nozzle at a constant speed (a dynamic dispense method).

The rinse treatment (washing treatment) using a rinse liquid can be performed according to a known rinse method. Examples of the rinse treatment method include a method of continuously ejecting a rinse liquid onto a support rotating at a constant speed (a rotary coating method), a method of immersing a support in a rinse liquid for a predetermined time (a dip method), and a method of spraying a rinse liquid to the surface of a support (a spray method).

In the rinse treatment, it is preferable to use a rinse liquid containing an organic solvent.

In the above-described pattern formation method according to the embodiment, since the above-described negative-working photosensitive resin composition is used, a high-resolution pattern having high sensitivity, reduced residues, and favorable shape can be formed.

(Cured Film)

The cured film according to the present embodiment is obtained by curing the above-described negative-working photosensitive resin composition according to the embodiment.

In the cured film of the embodiment, the tensile elastic modulus (E*) at a temperature of 175° C. in a case where the viscoelasticity is measured at a frequency of 1.0 Hz is 2.1 [GPa] or more, preferably 2.3 to 4.0 [GPa] and more preferably 2.5 to 3.5 [GPa].

According to the present embodiment, since the hardness of the cured film is further increased, the hollow structure can be reliably maintained even with high pressure applied during molding.

(Cured Film Production Method)

The cured film production method according to the present embodiment includes a step (i) of forming a photosensitive resin film on a support using the above-described negative-working photosensitive resin composition or photosensitive resist film according to the embodiment and a step (ii) of curing the photosensitive resin film to obtain a cured film.

The operation of the step (i) can be performed in the same manner as in [Film formation step] described above. The bake treatment can be performed under the conditions of, for example, a temperature of 50° C. to 100° C. and 0.5 to 30 minutes.

The curing treatment in the step (ii) can be performed under the conditions of, for example, a temperature of 100° C. to 250° C. and 0.5 to 2 hours.

The cured film production method according to the embodiment may include other steps in addition to the step (i) and the step (ii). For example, [Exposure step] described above may be included between the step (i) and the step (ii), and it is possible to obtain a cured film by selectively exposing the photosensitive resin film formed in the step (i), and curing the photosensitive resin film (pre-cured film) to which a bake (PEB) treatment has been performed as necessary.

According to the above-described cured film production method according to the embodiment, a cured film having a higher hardness is produced.

(Rolled Body)

The rolled body of the present embodiment is obtained by winding the above-described photosensitive resist film according to the embodiment around a winding core.

As the winding core, a paper tube, a wood tube, a plastic tube, or the like is used.

In the rolled body according to the present embodiment, since the above-described photosensitive resist film according to the embodiment is adopted, in a case where the laminate of photosensitive resin film/base film is wound around the winding core, cracks or crimping defects are less likely to occur, and rolling can be easily and reliably performed.

### EXAMPLES

Hereinafter, the present invention will be described in more detail with reference to Examples, but the present invention is not limited to the following Examples.

### Preparation of Negative-Working Photosensitive Resin Composition

### Examples 1 to 13 and Comparative Examples 1 to 3

Respective components listed in Table 1 were mixed and dissolved in methyl ethyl ketone (MEK), and the solution was filtered using a PTFE filter (a pore diameter of 1 μm, manufactured by Pall Corporation) to prepare each negative-working photosensitive resin composition (a MEK solution having a solid content of 80% to 85% by mass) of each example.

TABLE 1

| | Component (A) | | | | Component (I) | |
|---|---|---|---|---|---|---|
| | Component | Compound | Compound | Component | Component | Component |
| | (A1) | (m1) | (m2) | (M) | (I1) | (I2) |
| Example 1 | (A)-1 | (A)-3 | (A)-4 | (M)-1 | (I1)-1 | (I2)-1 |
| | [70] | [10] | [20] | [100] | [4.5] | [0.5] |
| Example 2 | (A)-1 | (A)-3 | (A)-4 | (M)-1 | (I1)-1 | (I2)-1 |
| | [75] | [12.5] | [12.5] | [100] | [4.5] | [0.5] |
| Example 3 | (A)-1 | (A)-3 | (A)-4 | (M)-1 | (I1)-1 | (I2)-1 |
| | [70] | [15] | [15] | [100] | [2.9] | [0.7] |
| Example 4 | (A)-1 | (A)-2 | (A)-4 | (M)-1 | (I1)-1 | (I2)-1 |
| | [70] | [10] | [20] | [100] | [2.9] | [0.7] |
| Example 5 | (A)-1 | (A)-3 | (A)-4 | (M)-1 | (I1)-1 | (I2)-1 |
| | [70] | [10] | [20] | [100] | [3.1] | [0.9] |
| Example 6 | (A)-1 | (A)-3 | (A)-4 | (M)-1 | (I1)-1 | (I2)-1 |
| | [70] | [20] | [10] | [100] | [2.9] | [0.7] |
| Example 7 | (A)-1 | — | (A)-4 | (M)-1 | (I1)-1 | (I2)-1 |
| | [70] | | [30] | [100] | [3.36] | [1.12] |
| Example 8 | (A)-1 | (A)-3 | (A)-4 | (M)-1 | (I1)-1 | (I2)-1 |
| | [70] | [15] | [15] | [50] | [2.0] | [0.5] |
| Example 9 | (A)-1 | (A)-3 | (A)-4 | (M)-1 | (I1)-1 | (I2)-1 |
| | [70] | [15] | [15] | [75] | [2.5] | [0.7] |
| Example 10 | (A)-1 | (A)-3 | (A)-4 | (M)-1 | (I1)-1 | (I2)-1 |
| | [70] | [15] | [15] | [167] | [3.36] | [1.12] |
| Example 11 | (A)-1 | (A)-3 | (A)-4 | (M)-1 | (I1)-1 | (I2)-1 |
| | [70] | [15] | [15] | [45] | [1.85] | [0.5] |
| Example 12 | (A)-1 | (A)-3 | (A)-4 | (M)-1 | (I1)-1 | (I2)-1 |
| | [80] | [10] | [10] | [100] | [2.9] | [0.7] |
| Example 13 | (A)-1 | (A)-3 | (A)-4 | (M)-1 | (I1)-1 | (I2)-1 |
| | [85] | [7.5] | [7.5] | [100] | [2.9] | [0.7] |
| Comparative | (A)-1 | — | — | (M)-1 | (I1)-1 | (I2)-1 |
| Example 1 | [100] | | | [100] | [4.5] | [0.5] |
| Comparative | (A)-1 | (A)-3 | (A)-4 | (M)-1 | (I1)-1 | (I2)-1 |
| Example 2 | [90] | [5] | [5] | [100] | [4.5] | [0.5] |
| Comparative | (A)-1 | (A)-2 | (A)-4 | (M)-1 | (I1)-1 | (I2)-1 |
| Example 3 | [90] | [5] | [5] | [25] | [1.35] | [0.45] |

In Table 1, each abbreviation has the following meaning. The numerical values in the parentheses are the blending amount (parts by mass, in terms of solid content) of the respective components.

(A)-1: epoxy group-containing resin represented by Formula (A1l), trade name “JER-157S70”, manufactured by Mitsubishi Chemical Corporation

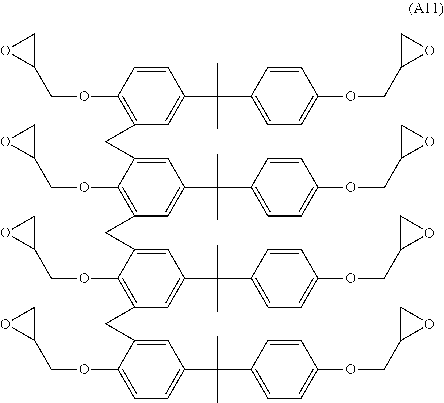 [SMILES: CC(C)(c1ccc(OCC2CO2)cc1)c1ccc(OCC2CO2)c(Cc2cc(C(C)(C)c3ccc(OCC4CO4)cc3)cc(Cc3cc(C(C)(C)c4ccc(OCC5CO5)cc4)cc(Cc4cc(C(C)(C)c5ccc(OCC6CO6)cc5)ccc4OCC4CO4)c3OCC3CO3)c2OCC2CO2)c1]

(A)-2: compound represented by Chemical Formula (m1-1), trade name “CELLOXIDE 8010”, manufactured by Daicel Corporation

(A)-3: compound represented by Chemical Formula (m1-2), trade name “CELLOXIDE 2021P”, manufactured by Daicel Corporation

(A)-4: compound represented by Chemical Formula (m2-1), trade name “TEPIC-VL”, manufactured by Nissan Chemical Industries, Ltd.

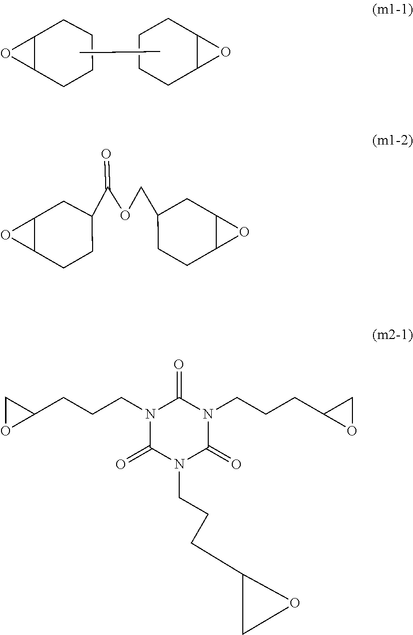

(M)-1: silica component (a), trade name “MEK-EC-2130Y”, manufactured by Nissan Chemical Industries, Ltd.; primary particle diameter (p of 15 nm (volume average value), methyl ethyl ketone dispersion liquid having a silica component concentration of 31% by mass

(I1)-1: cationic polymerization initiator represented by Chemical Formula (I1-1), trade name “CPI-310B”, manufactured by San-Apro Ltd.

(I2)-1: cationic polymerization initiator represented by Chemical Formula (I2-1), trade name “CPI-410S”, manufactured by San-Apro Ltd.

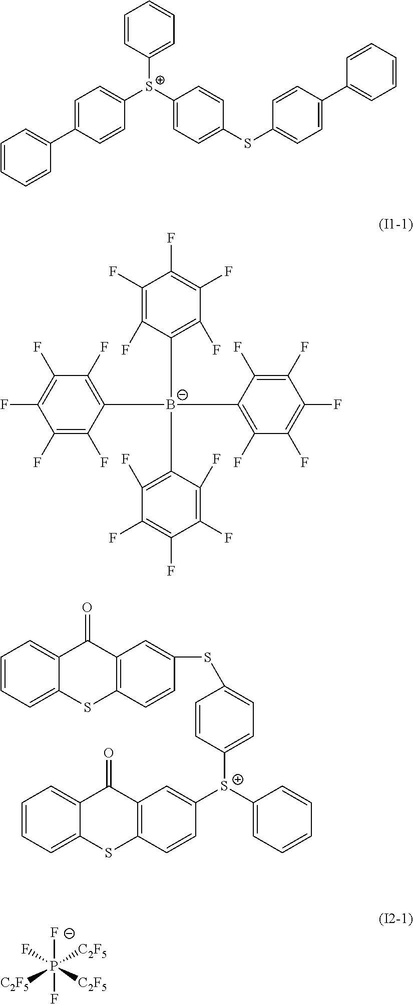

[Measurement of Martens Hardness of Photosensitive Resin Film]

The negative-working photosensitive resin composition of each example was applied onto a silicon wafer and baked at 90° C. for 5 minutes to form a photosensitive resin film having a film thickness of 20 μm on the silicon wafer. The Martens hardness [N/mm²] of the photosensitive resin film was measured by a nanoindentation method shown below. The results are shown in Table 2.

Nanoindentation Method
Evaluation method: micro hardness test in conformity with ISO14577 with a FISCHERSCOPE HM2000 measuring device (manufactured by FISCHER INSTRUMENTS K.K.)
Measurement conditions: maximum test load: 30 mN, load application time: 20 seconds, creep time: 5 seconds, temperature: 25° C.

[Evaluation of Roll]

The negative-working photosensitive resin composition of each example was applied onto a base film using an applicator with a width of 200 mm and a thickness of 20 μm, and dried to form a photosensitive resin layer.

Next, while pressure-bonding the top of the photosensitive resin layer with a rubber roller so that no air bubbles remain and protecting the photosensitive resin layer with a cover film having a width of 200 mm, a laminate (cover film/photosensitive resin layer/base film) of 150 μm was wound around a winding core on the photosensitive resin layer, thereby producing a master roll.

At this time, those with cracks or crimping defects were evaluated as x, and those without cracks or crimping defects were evaluated as o. The results are shown in Table 2.

<Production of Photosensitive Resist Film>

The negative-working photosensitive resin composition of each example was applied onto a base film using an applicator, and heated at a temperature of 500 for 3 minutes, and subjected to a bake treatment (PAB) at 70° C. for 3 minutes to form a photosensitive resin film having a film thickness of 20 μm.

Next, a cover film was laminated on the photosensitive resin film to obtain a photosensitive resist film.

<Production of Cured Film>

Step (i):

The cover film on the photosensitive resin film in the photosensitive resist film obtained above was peeled off, and the exposed photosensitive resin film and a silicon wafer were laminated under the conditions of 90° C., 0.3 MPa, and 0.5 μm/min.

Next, the base film in contact with the photosensitive resin film was peeled off, and the photosensitive resin film was irradiated with i-rays (wavelength: 365 nm) at an irradiation amount of 200 mJ/cm². Thereafter, on a hot plate at 90° C., heating was performed after the exposure for 5 minutes to obtain a pre-cured film.

Step (ii):

Thereafter, the obtained pre-cured film was heated at 200° C. for 1 hour in a nitrogen atmosphere to be cured, thereby obtaining a desired cured film.

[Evaluation of Laminating Properties]

In a case where the exposed photosensitive resin film and the silicon wafer were laminated under the above-described conditions in the step (i), laminating properties were evaluated according to the following evaluation standard. The results are shown in Table 2.

Evaluation Standard

o: exposed photosensitive resin film was able to adhere to the silicon wafer.

Δ: there was partial adhesion failure (less than 5% of the total area).

x: there was adhesion failure such as peeling (5% or more of the total area).

[Measurement of Tensile Elastic Modulus (E*) of Cured Film]

The tensile elastic modulus (E*) of the cured film obtained in the step (ii) was measured as follows.

The cured film was peeled off from the silicon wafer, and the tensile elastic modulus (E*) [GPa] of the cured film at 175° C. was measured by the following evaluation device and measurement conditions. The results are shown in Table 2.
Evaluation device: Reogel E-4000 (manufactured by UBM)
Measurement conditions: tensile mode, frequency 1.0 Hz, distance between chucks 10 mm

As the tensile elastic modulus (E*) is higher, the hardness of the cured film is higher.

<Pattern Formation Method>

Film Formation Step:

The cover film on the photosensitive resin film in the photosensitive resist film obtained above was peeled off, and the exposed photosensitive resin film and a silicon wafer were laminated under the conditions of 90° C., 0.3 MPa, and 0.5 in/min.

Exposure Step:

Next, the base film in contact with the photosensitive resin film was peeled off, and through a negative mask having an opening pattern with a hole diameter of 20 μm, the photosensitive resin film was irradiated with i-rays (365 nm) at an irradiation amount of 300 mJ/cm². Thereafter, on a hot plate at 90° C., heating was performed after the exposure for 5 minutes.

Development Step:

Next, the exposed silicon wafer was developed at 23° C. with propylene glycol monomethyl ether acetate (PGMEA) for 5 minutes, and then subjected to a rinse treatment and drying to form a negative-working pattern.

[Evaluation of Lithography Characteristics]

A fine structure of the formed negative-working pattern was observed using a scanning electron microscope (S-4300, manufactured by Hitachi High-Technologies Corporation). Specifically, the presence or absence of residues in the negative-working pattern and the cross-sectional shape of the opening pattern having a hole diameter of 20 μm were observed, and lithography characteristics were evaluated according to the following evaluation standard. The results are shown in Table 2.

Evaluation Standard

o: rectangular pattern was obtained with no residue.

x: tapered pattern was obtained.

TABLE 2

| | | | | Film character- | |
|---|---|---|---|---|---|
| | | | | istics after curing | |
| | | | | Tensile | Lithog- |
| | Martens | | | elastic | raphy |
| | hardness | | Laminate | modulus | character- |
| | [N/mm²] | Rolling | properties | (E*) [GPa] | istics |
| Example 1 | 52 | ∘ | ∘ | 3.0 | ∘ |
| Example 2 | 103 | ∘ | ∘ | 3.0 | ∘ |
| Example 3 | 45 | ∘ | ∘ | 3.0 | ∘ |
| Example 4 | 55 | ∘ | ∘ | 2.9 | ∘ |
| Example 5 | 52 | ∘ | ∘ | 3.0 | ∘ |
| Example 6 | 33 | ∘ | ∘ | 2.9 | ∘ |
| Example 7 | 63 | ∘ | ∘ | 3.0 | ∘ |
| Example 8 | 21 | ∘ | ∘ | 2.5 | ∘ |
| Example 9 | 28 | ∘ | ∘ | 2.6 | ∘ |
| Example 10 | 152 | ∘ | ∘ | 3.8 | ∘ |
| Example 11 | 15 | ∘ | ∘ | 2.2 | ∘ |
| Example 12 | 170 | ∘ | ∘ | 3.0 | ∘ |
| Example 13 | 200 | ∘ | ∘ | 3.0 | ∘ |
| Comparative | 260 | x | x | 3.1 | x |
| Example 1 | | | | | |
| Comparative | 235 | x | Δ | 3.0 | x |
| Example 2 | | | | | |
| Comparative | 15 | ∘ | ∘ | 2.0 | ∘ |
| Example 3 | | | | | |

From the results shown in Table 2, in the negative-working photosensitive resin compositions of Examples 1 to 13, in which the Martens hardness of the photosensitive resin film was less than 235 [N/mm²] and the tensile elastic modulus (E*) of the cured film was 2.1 [GPa] or more, it could be confirmed that a cured film having a higher hardness could be obtained, and rolling was easy and laminating properties were excellent, as compared with the negative-working photosensitive resin compositions of Comparative Examples 1 to 3.

In addition, with the negative-working photosensitive resin compositions of Examples 1 to 13, it could be confirmed that a pattern with favorable shape could be formed.

1. A negative-working photosensitive resin composition, which forms a negative-working pattern by a development using a developing solution containing an organic solvent, comprising:
an epoxy group-containing resin (A);
a metal oxide (M); and
a cationic polymerization initiator (I),
wherein, when the negative-working photosensitive resin composition is applied onto a silicon wafer and a bake treatment is performed at 90° C. for 5 minutes to obtain a photosensitive resin film having a film thickness of 20 μm, the film has a Martens hardness of less than 235 [N/mm²], and
when a viscoelasticity of a cured film, which is obtained by exposing the photosensitive resin film to i-rays at an irradiation amount of 200 mJ/cm², performing a bake treatment after the exposure at 90° C. for 5 minutes, and then performing a bake treatment at 200° C. for 1 hour to cure the photosensitive resin film, is measured at a frequency of 1.0 Hz, a tensile elastic modulus (E*) of the cured film at a temperature of 175° C. is 2.1 [GPa] or more.

2. The negative-working photosensitive resin composition according to claim 1, wherein a content of the metal oxide (M) is more than 30 parts by mass and 180 parts by mass or less with respect to 100 parts by mass of the epoxy group-containing resin (A).

3. The negative-working photosensitive resin composition according to claim 1,
wherein the epoxy group-containing resin (A) contains a resin (A1) represented by Formula (A1), 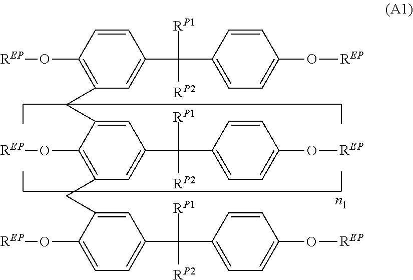
wherein Rp1 and Rp2 each independently represents a hydrogen atom or an alkyl group having 1 to 5 carbon atoms, a plurality of Rp1's may be the same as or different from one another, a plurality of Rp2's may be the same as or different from one another, n1 represents an integer of 1 to 5, R^{EP} represents an epoxy group-containing group, and a plurality of R^{EP}'s may be the same as or different from one another.

4. The negative-working photosensitive resin composition according to claim 1, wherein the epoxy group-containing resin (A) contains a compound (m1) including a partial structure represented by Formula (m1), 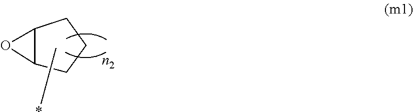
wherein n₂ represents an integer of 1 to 4, and * represents a bonding site.

5. The negative-working photosensitive resin composition according to claim 1, wherein the epoxy group-containing resin (A) contains a compound (m2) represented by Formula (m2), 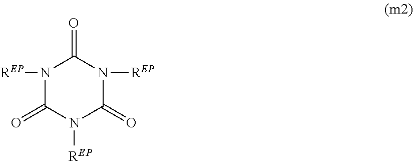
wherein R^{EP} represents an epoxy group-containing group, and a plurality of R^{EP}'s may be the same as or different from one another.

6. The negative-working photosensitive resin composition according to claim 5,
wherein the epoxy group-containing resin (A) contains the resin (A1), the compound (m1), and the compound (m2), and
a total amount of the compound (m1) and the compound (m2) with respect to a total amount of the resin (A1), the compound (m1), and the compound (m2) is 15% by mass or more.

7. The negative-working photosensitive resin composition according to claim 1,
wherein a content of the epoxy group-containing resin (A) with respect to a total amount of the epoxy group-containing resin (A), the cationic polymerization initiator (I), and the metal oxide (M) is 35% by mass or more and less than 70% by mass.

8. A pattern formation method comprising:
forming a photosensitive resin film on a support using the negative-working photosensitive resin composition according to claim 1;
exposing the photosensitive resin film; and
developing the exposed photosensitive resin film with a developing solution containing an organic solvent to form a negative-working pattern.

9. A cured film obtained by curing the negative-working photosensitive resin composition according to claim 1.

10. A cured film production method comprising:
forming a photosensitive resin film on a support using the negative-working photosensitive resin composition according to claim 1; and
curing the photosensitive resin film to obtain a cured film.

11. A photosensitive resist film obtained by laminating a negative-working photosensitive resin film containing an epoxy group-containing resin (A), a metal oxide (M), and a cationic polymerization initiator (I) on a base film:
wherein, when the photosensitive resin film is laminated on a silicon wafer to a film thickness of 20 μm, the photosensitive resin film has a Martens hardness of less than 235 [N/mm²], and
when a viscoelasticity of a cured film, which is obtained by exposing the photosensitive resin film to i-rays at an irradiation amount of 200 mJ/cm², performing a bake treatment after the exposure at 90° C. for 5 minutes, and then performing a bake treatment at 200° C. for 1 hour to cure the photosensitive resin film, is measured at a frequency of 1.0 Hz, a tensile elastic modulus (E*) of the cured film at a temperature of 175° C. is 2.1 [GPa] or more.

12. The photosensitive resist film according to claim 11, wherein a content of the metal oxide (M) is more than 30 parts by mass and 180 parts by mass or less with respect to 100 parts by mass of the epoxy group-containing resin (A).

13. The photosensitive resist film according to claim 11,
wherein the epoxy group-containing resin (A) contains a resin (A1) represented by Formula (A1), 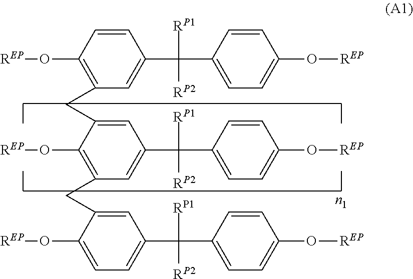
wherein R^{p1} and R^{p2} each independently represents a hydrogen atom or an alkyl group having 1 to 5 carbon atoms, a plurality of R^{p1}'s may be the same as or different from one another, a plurality of R^{p2}'s may be the same as or different from one another, n₁ represents an integer of 1 to 5, R^{EP} represents an epoxy group-containing group, and a plurality of R^{EP}'s may be the same as or different from one another.

14. The photosensitive resist film according to claim 11, wherein the epoxy group-containing resin (A) contains a compound (m1) including a partial structure represented by Formula (m1), 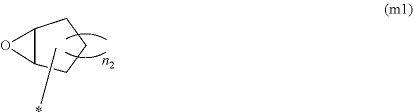
wherein n₂ represents an integer of 1 to 4, and * represents a bonding site.

15. The photosensitive resist film according to claim 11,
wherein the epoxy group-containing resin (A) contains a compound (m2) represented by Formula (m2), 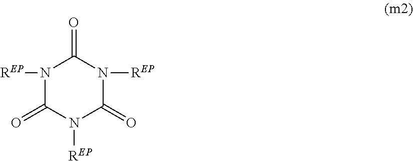
wherein R^{EP} represents an epoxy group-containing group, and a plurality of R^{EP}'s may be the same as or different from one another.

16. The photosensitive resist film according to claim 15,
wherein the epoxy group-containing resin (A) contains the resin (A1), the compound (m1), and the compound (m2), and
a total amount of the compound (m1) and the compound (m2) with respect to a total amount of the resin (A1), the compound (m1), and the compound (m2) is 15% by mass or more.

17. The photosensitive resist film according to any-one-el claim 11, wherein a content of the epoxy group-containing resin (A) with respect to a total amount of the epoxy group-containing resin (A), the cationic polymerization initiator (I), and the metal oxide (M) is 35% by mass or more and less than 70% by mass.

18. The photosensitive resist film according to any-one-el claim 11, wherein the photosensitive resist film comprises a laminate in which the photosensitive resin film and a cover film are laminated on the base film in this order.

19. A pattern formation method comprising:
forming a photosensitive resin film on a support using the photosensitive resist film according to claim 11;
exposing the photosensitive resin film; and
developing the exposed photosensitive resin film with a developing solution containing an organic solvent to form a negative-working pattern.

20. A cured film production method comprising:
forming a photosensitive resin film on a support using the photosensitive resist film according to claim 11; and
curing the photosensitive resin film to obtain a cured film.

21. A rolled body obtained by winding the photosensitive resist film according to claim 11 around a winding core.
